(19) United States
(12) Patent Application Publication
(10) Pub. No.: US 2017/0213996 A1
(43) Pub. Date: Jul. 27, 2017

(54) ORGANIC ELECTROLUMINESCENT ELEMENT

(71) Applicant: KONICA MINOLTA, INC., Tokyo (JP)

(72) Inventors: Shun FURUKAWA, Sagamihara-shi, Kanagawa (JP); Toshiyuki KINOSHITA, Hino-shi, Tokyo (JP); Shigeru KOJIMA, Hino-shi, Tokyo (JP); Kazuhiro YOSHIDA, Hino-shi, Tokyo (JP); Takeshi HAKII, Sagamihara-shi, Kanagawa (JP)

(21) Appl. No.: 15/316,780

(22) PCT Filed: Jul. 10, 2015
(86) PCT No.: PCT/JP2015/069887

§ 371 Date: Dec. 6, 2016

(30) Foreign Application Priority Data
Jul. 18, 2014 (JP) 2014-147888

(51) Int. Cl. H01L 51/52

(52) U.S. Cl. CPC H01L 51/5234; H01L 51/5212; H01L 51/5206; H01L 51/5228; H01L 2251/301; H01L 2251/558

(57) ABSTRACT

Provided is an organic electroluminescent element that makes it possible to use a silver electride of a thin film as a cathode. The organic electroluminescent element is provided with a transparent electrode comprising silver as a main component, a counter electrode arranged so as to face the transparent electrode, and a light-emitting unit that is sandwiched between the transparent electrode and the counter electrode. A calcium-containing layer is provided adjacent to the transparent electrode between the transparent electrode and the light-emitting unit. The transparent electrode is used as a cathode and the counter electrode is used as an anode.

### TECHNICAL FIELD

The present invention relates to an organic electroluminescent element.

### BACKGROUND ART

In recent years, an organic electroluminescent element (so-called “organic EL element”) utilizing electroluminescence (hereinafter, referred to as “EL”) of an organic material has received attention as surface emitting bodies such as: backlights for various kinds of displays; display boards for signboards, emergency lights and the like; and lighting sources. The organic EL element is a thin-film-type completely solid-state element that can emit light at a low voltage of approximately several volts to several ten volts, and has many excellent advantages such as high luminance, high light emission efficiency, thin type and light weight.

Such an organic EL element has a configuration in which a light-emitting layer including an organic material is sandwiched between two electrodes, and emitted light generated by the light-emitting layer is externally extracted through the electrode. Accordingly, at least one of the two electrodes is required to be a transparent electrode having a low electric resistance and a high light-transmitting property.

Here, there are usually used, as a transparent electrode, oxide semiconductor-based materials having a high light-transmitting property such as indium tin oxide (SnO₂—In₂O₃:Indium Tin Oxide:ITO) and indium zinc oxide (IZO). However, since these materials are formed mainly by a sputtering film deposition method, of the like, in a case where each of these materials is used as, for example, an upper electrode, a light-emitting functional layer is damaged at the time of film deposition. Furthermore, since indium of a rear metal is used in ITO, the material cost is expensive and an annealing treatment at approximately 300° C. is required after the film deposition in order to lower its resistance, and thus there has been a limit to further lowering the resistance.

Accordingly, there have been proposed: a transparent electrode which has a low resistance while maintaining a light-transmitting property, by forming an electrode layer using silver or an alloy containing silver as a main component adjacent to a nitrogen-containing layer to thereby give a silver electrode having a small thickness; and an organic EL element in which performance enhancement is achieved by the use of the transparent electrode (for example, refer to Patent Literature 1 below).

### CITATION LIST

### Patent Literature

PTL 1: WO 2013/073356

### SUMMARY OF INVENTION

### Technical Problem

However, although the silver electride having a small thickness has a sufficient light-transmitting property and electric conductivity, the silver constituting the electrode has a high work function, and thus the electrode is poor in an electron injecting property, with the result that it is difficult to use the silver electride having a small thickness as a cathode of the organic EL element.

Accordingly, an object of the present invention is to provide an organic electroluminescent element that makes it possible to use a silver electride having a small thickness as a cathode.

### Solution to Problem

The organic EL element of the present invention for the purpose of achieving the above object includes: a transparent electrode composed of silver as a main component; a counter electrode arranged so as to face the transparent electrode; and a light-emitting unit sandwiched between the transparent electrode and the counter electrode. Furthermore, a calcium-containing layer is provided adjacent to the transparent electrode between the transparent electrode and the light-emitting unit, and the transparent electrode is used as a cathode and the counter electrode is used as an anode.

### Advantageous Effects of Invention

As explained above, according to the present invention, the silver electride having a small thickness can be used as a cathode in the organic EL element.

### BRIEF DESCRIPTION OF DRAWINGS

FIG. 1 is a schematic cross-sectional view showing a configuration of an organic EL element according to a first embodiment of the present invention.

FIG. 2 is a schematic cross-sectional view showing a configuration of a modification of the organic EL element according to the first embodiment of the present invention.

FIG. 3 is a schematic cross-sectional view showing a configuration of the organic EL element (stack structure) according to a second embodiment of the present invention.

FIG. 4 is a schematic cross-sectional view showing a configuration of Modification 1 of the organic EL element according to the second embodiment of the present invention.

FIG. 5 is a schematic cross-sectional view showing a configuration of Modification 2 of the organic EL element according to the second embodiment of the present invention.

FIG. 6 is a structural cross-sectional view explaining the top-emission type organic EL element produced in Example.

FIG. 7 is an SEM image of an organic EL element 101 produced in Example.

FIG. 8 is an SEM image of an organic EL element 105 produced in Example.

FIG. 9 is an SEM image of an organic EL element 110 produced in Example.

FIG. 10 is an SEM image of an organic EL element 113 produced in Example.

FIG. 11 is an SEM image of Comparative Example 1 produced in Example.

FIG. 12 is an SEM image of Comparative Example 2 produced in Example.

FIG. 13 is an SEM image (No. 1) of the organic EL element 105 produced in Example after the storing at a high temperature.

FIG. 14 is an SEM image (No. 2) of the organic EL element 105 produced in Example after the storing at a high temperature.

FIG. 15 is an SEM image of the organic EL element 110 produced in Example after the storing at a high temperature.

FIG. 16 is an SEM image of the organic EL element 113 produced in Example after the storing at a high temperature.

### DESCRIPTION OF EMBODIMENTS

Hereinafter, the embodiments of the organic EL element of the present invention will be described by referring the drawings, in the following order.

1. First embodiment: Organic EL element (Top-emission type)
1-1. Modification of the organic EL element (Bottom emission type)
2. Second embodiment: Organic EL element of stack structure (example in which the transparent electrode is provided between two light-emitting units)
2-1. Modification 1 of the organic EL element
2-2. Modification 2 of the organic EL element
3. Third embodiment: Uses of the organic EL element

### 1. First Embodiment: Organic EL Element

### (Top-Emission Type)

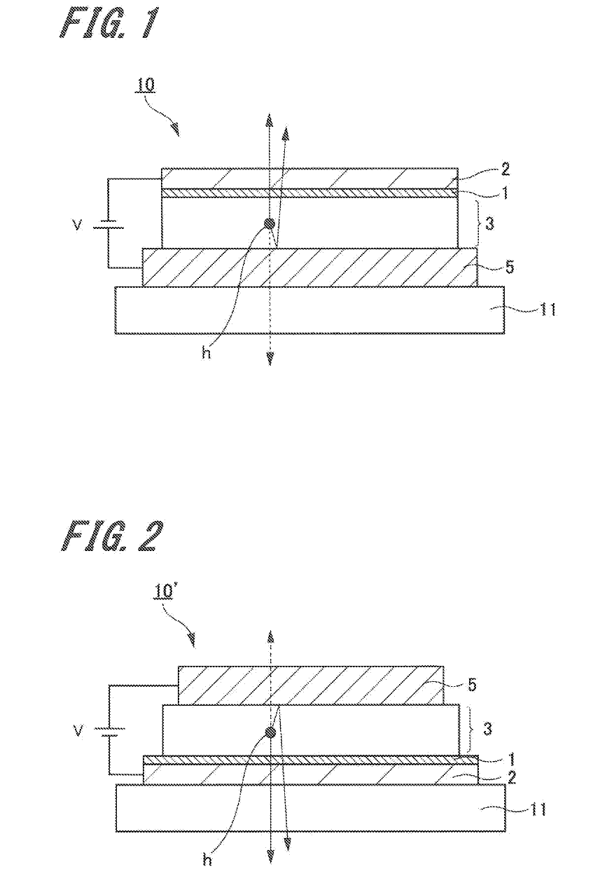

FIG. 1 is a schematic cross-sectional view showing a configuration of the organic EL element according to a first embodiment of the present invention. The organic EL element 10 shown in the figure has a configuration in which a counter electrode 5, a light-emitting unit 3, a calcium-containing layer 1, and a transparent electrode 2 are provided on one main surface side (internal extraction side) of a substrate 11, in this order. Among them, the transparent electrode 2 is composed of silver (Ag) or an alloy containing silver as a main component.

The features of the organic EL element 10 of the present embodiment are that the calcium-containing layer 1 is provided adjacent to the transparent electrode 2, between the transparent electrode 2 and the light-emitting unit 3, and that the transparent electrode 2 is used as a cathode and the counter electrode 5 is used as an anode. Furthermore, in the present embodiment, there will be described the configuration of the organic EL element having the top-emission structure in which emitted light (hereinafter, referred to as emitted light h) is extracted from at least the opposite side of the substrate 11.

Note that the layer construction of the organic EL element 10 is not limited and may be a general layer construction. In addition, the organic EL element 10 has a configuration of including a sealing member which seals the light-emitting unit 3 on one main side of the substrate 11, and furthermore a protective film and the like may be provided.

Hereinafter, each part of the organic EL element 10 of the present embodiment will be described in detail in order of the substrate 11, the counter electrode 5, the light-emitting unit 3, the calcium-containing layer 1, the transparent electrode 2, and the other structural elements (auxiliary electrode, sealing member, protective film, and protective plate).

### <Substrate 11>

The substrate 11 is made of, for example, glass, plastics, or the like, and is not limited thereto. In addition, the substrate 11 may be transparent or opaque. For example, in a case where an organic EL element 10 extracts light also from the substrate 11 side, the substrate 11 is transparent. Furthermore, in a case where flexibility is imparted to the organic EL element 10, a resin film is preferable.

Examples of the glasses include silica glass, soda lime silica glass, lead glass, borosilicate glass, non-alkali glass, and the like. From the viewpoints of adhesion to the counter electrode 5, durability and smoothness, as necessary, the surface of those glass materials is subjected to physical treatment such as grinding, or there is formed, on the surface, a film made of inorganic materials or organic materials, or a hybrid film obtained by combination of those films.

Examples of the resin films include, for example, polyesters such as polyethylene terephthalate (PET) and polyethylene naphthalate (PEN), polyethylene, polypropylene, cellulose esters or derivative thereof such as cellophane, cellulose diacetate, cellulose triacetate (TAC), cellulose acetate butylate, cellulose acetate propionate (CAP), cellulose acetate phthalate and cellulose nitrate, polyvinylidene chloride, polyvinyl alcohol, polyethylene vinyl alcohol, syndiotactic polystyrene, polycarbonate, norbornen resin, polymethylpenten, polyether ketone, polyimide, polyether sulphone (PES), polyphenylene sulfide, polysluphones, polyether imide, polyether ketone imide, polyamide, fluoro resin, Nylon, polymethyl methacrylate, acryl or polyallylates, cycloolefins-based resins such as Alton (commercial name of JSR) or APEL (commercial name of Mitsui Chemicals).

A film made of inorganic materials or organic materials, or a hybrid film obtained by combining those films may be formed on the surface of the resin film. Each of these films or hybrid films is preferably a barrier film (also referred to as barrier membrane, and the like) having a water vapor permeability (25±0.5° C., relative humidity 90±2% RH) measured by the method in accordance with JIS-K-7129-1992 of 0.01 g/(m²·24 hr) or less. Furthermore, each of these films is preferably a high barrier film having an oxygen permeability measured by the method in accordance with JIS-K-7126-1987 of 10⁻³ ml/(m²·24 hrs·atm) or less and a water vapor permeability of 10⁻⁵ g/(m²·24 hr) or less.

A material that forms the above barrier film may be a material having a function of suppressing the intrusion of substances such as water vapor and oxygen which deteriorate the element, and for example, there can be used silicon oxide, silicon dioxide, silicon nitride, and the like. Furthermore, in order to improve fragility of the barrier film, it is more preferably to impart a laminated structure of the inorganic layer and a layer of organic material (organic layer) to the barrier film. The lamination orders of the inorganic layer and the organic layer are not particularly limited, and it is preferable to alternately laminate the both layers a plurality of times.

The method of forming the barrier film is not particularly limited, and there can be used, for example, a vacuum deposition method, a sputtering method, a reactive sputtering method, a molecular beam epitaxy method, a cluster ion beam method, an ion plating method, a plasma polymerization method, an atmospheric pressure plasma polymerization method, a plasma CVD method, a laser CVD method, a thermal CVD method, a coating method, and the like, and particularly preferable is the atmospheric pressure plasma polymerization method described in Japanese Patent Application Laid-Open Publication No. 2004-68143.

The above is a case where the substrate 11 is transparent, and in a case where the substrate 11 is opaque, it is possible to use, for example, a metal substrate such as aluminum or stainless steel, a film or an opaque resin substrate, a substrate made of ceramics, and the like.

### <Counter Electrode 5>

The counter electrode 5 is provided in a state of sandwiching the light-emitting unit 3 between the counter electrode 5 and the transparent electrode 2, and is used as an anode, here. Accordingly, at least the interface layer to be in contact with the light-emitting unit 3 is composed of a material which is suitable as the anode.

In the present embodiment, the counter electrode is constituted as a reflective electrode in which the emitted light h emitted from the light-emitting layer of the light-emitting unit 3 is reflected to the side opposite to the substrate 11. However, in a case where the organic EL element 10 is configured such that the light is extracted also from the substrate 11 side, the counter electrode 5 is composed of a material having a light-transmitting property.

The counter electrode 5 constituting the anode as described above is as follows.

### [Anode]

There is used, as the counter electrode 5 constituting the anode of the organic EL element 10, an electrode material formed of a metal, an alloy, an electrically conductive compound, or a mixture thereof, each having a high work function (4 eV or more, preferably 4.5 V or more). Examples of the electrode materials include: a metal such as Au, Ag or Cu; and an electrically conductive transparent material such as CuI, indium tin oxide (ITO), SnO₂ or ZnO. Furthermore, a material capable of forming an amorphous transparent conductive film such as IDIXO (In₂O₃—ZnO) may also be used.

In the counter electrode 5 used as an anode, a thin film is formed by vapor deposition, sputtering or the like of these electrode materials, and pattern having a desired shape is formed by photolithography. Alternatively, in case where patterning accuracy is not required so much (about 100 μm or more), a certain pattern may be formed via a mask having the desired shape, when the above electrode material is formed by a vapor deposition method or a sputtering method.

Alternatively, in case where there is used a material capable of being coated, such as a conductive organic compound, a wet film deposition method such as a printing method or a coating method can also be used. Moreover, the sheet resistance as an anode is preferably hundreds of Q/square or less.

A thickness of the anode depends on the kinds of materials, and is usually selected in the range of 10 nm to 1 μm, preferably in the range of 10 nm to 200 nm, in consideration of the permeability or reflectance.

### <Light-Emitting Unit 3>

The light-emitting unit 3 is a layer which includes at least a light-emitting layer composed of an organic material. The whole layer structure of the light-emitting unit 3 described above is not limited, and may be a general layer structure. Furthermore, there is exemplified, as one example of the light-emitting unit 3, a configuration in which the [positive hole-injecting layer/positive hole transport layer/light-emitting layer/electron transport layer/electron-injecting layer] are laminated from the counter electrode 5 side used as an anode, and the layers other than the light-emitting layer are provided as necessary.

Among them, the light-emitting layer is a layer in which an electron injected from the cathode side and a positive hole injected from the anode side are recombined to thereby emit light, and the portion that emits light may be in the light-emitting layer or at the interface of the light-emitting layer with the adjacent layer. In the light-emitting layer described above, the luminescent materials may contain a phosphorescent material, may contain a fluorescent material, or may contain both of the phosphorescent material and the fluorescent material. Furthermore, the light-emitting layer preferably has a configuration in which each of these luminescent materials is used as a guest material, and furthermore, a host material is contained.

The positive hole-injecting layer and the positive hole transport layer may be provided as a positive hole transport/injection layer having a positive hole transporting property and a positive hole injecting property.

Furthermore, the electron transport layer and the electron-injecting layer may be provided as an electron transport/injection layer having an electron transporting property and an electron injecting property.

In addition, among these layers, for example, there is a case where the positive hole-injecting layer and the electron-injecting layer are formed by an inorganic material. Additionally, the calcium-containing layer 1 described below may be provided so as to have a role as the electron-injecting layer.

Furthermore, in the light-emitting unit 3, there may be laminated a positive hole-blocking layer, an electron blocking layer, and the like, at required positions as necessary, in addition to these layers.

Moreover, although illustration is omitted, the light-emitting unit 3 may have a configuration in which there is laminated a plurality of light-emitting functional layers, each of which includes a light-emitting layer which generates emitted light of each color in the respective wavelength regions. Each light-emitting functional layer may have a similar configuration to the above-described light-emitting unit 3, or each has a different layer configuration, or the layers may be directly laminated or may be laminated via an intermediate layer. The intermediate layer is generally any of an intermediate electrode, an intermediate conductive layer, an electric charge-generating layer, an electron withdrawing layer, a connecting layer or an intermediate insulation layer, and any known material configuration can be used as long as the layer has functions of supplying an electron to the adjacent layer of the anode side and of supplying a positive hole to the adjacent layer of the cathode side.

### (Film Deposition Method for Light-Emitting Unit)

The light-emitting unit 3 as described above can be obtained by sequential film deposition of a material constituting each layer by a known thin film formation method such as a vacuum vapor deposition method, a spin coating method, a casting method, an LB method, an inkjet method, a printing method. The vacuum vapor deposition method or the spin coating method is particularly preferable from the viewpoints that a homogeneous layer is easily obtained and a pinhole is hard to be generated. Furthermore, deposition methods different for each layer may be applied. When the vapor deposition method is adopted for depositon of each layer, although the vapor deposition conditions are different depending on the kind of the compound to be used or the like, it is generally desirable to appropriately select each condition in the ranges of a heating temperature of boat that houses a compound of 50° C. to 450° C., a degree of vacuum 1×10⁻⁶ to 1×10⁻² Pa, a vapor-deposition rate of 0.01 nm/sec to 50 nm/sec, a temperature of substrate of −50° C. to 300° C., and a thickness of 0.1 nm to 5 μm.

### <Calcium-Containing Layer 1>

The calcium-containing layer 1 is a layer which contains calcium (Ca) and which is provided so as to be in contact with to the transparent electrode 2 between the transparent electrode 2 and the light-emitting unit 3. The calcium-containing layer 1 is, as shown also in the following Examples, a layer for making the film quality of the transparent electrode 2 excellent, and for making the silver electride having a small thickness constituting the transparent electrode 2 function as a cathode, and has features that the calcium-containing layer 1 is arranged adjacent to the transparent electrode 2 in a thickness range of 2.0 nm or less.

It is important that the above calcium-containing layer 1 has such a degree of film thickness that an interaction with the transparent electrode 2 can be obtained without inhibiting the light-transmitting property of the transparent electrode 2. Accordingly, the calcium-containing layer 1 may be a film isolated in an island shape having, for example, at least one atomic layer of calcium (Ca) atom on the light-emitting unit 3, may be a film having a plurality of holes, or may be a continuous film.

The calcium-containing layer 1 is not particularly limited as long as the layer 1 contains calcium (Ca), may be formed by a sole material of calcium (Ca), or may be formed by a mixed material with other compounds. For example, the calcium-containing layer 1 may be constituted so as to contain not only the calcium (Ca), but also calcium oxide (CaO) in a part or in the whole. Furthermore, for example, the calcium-containing layer 1 may be configured by containing a metal material such as silver (Ag) constituting the transparent electrode 2.

From the viewpoint of stabilizing the film quality of the transparent electrode 2, it is preferable that the calcium-containing layer 1 is a layer constituted by containing calcium (Ca) as a main component. The main component in the present invention means that the mass ratio of the calcium (Ca) to the total mass of the calcium-containing layer 1 is 50% by mass or more, preferably 70% by mass or more.

Furthermore, the film thickness of the calcium-containing layer 1 is preferably within the range of 2.0 nm or less, further preferably within the range of 0.5 to 2.0 nm. Note that, here, the film thickness means an average thickness. Moreover, the film thickness is defined as a thickness adjusted by, for example, a forming rate and forming period of time of the calcium-containing layer 1.

The setting of the film thickness of the calcium-containing layer 1 to be 0.5 nm or more lowers the driving voltage and enhances the light emission efficiency, in the organic EL element 10, as shown in the following Examples. Furthermore, the setting of the film thickness of the calcium-containing layer 1 to be 2.0 nm or less makes it possible to obtain a sufficient interaction with the silver atom constituting the transparent electrode 2 without inhibiting the optical properties of the organic EL element 10.

Accordingly, it is possible to form the transparent electrode 2 on the calcium-containing layer 1 so as to have a stable film quality and a uniform thickness even with a small thickness.

Namely, there is obtained the transparent electrode 2 on the calcium-containing layer 1 in an excellent film deposition state, as shown in the SEM images of Examples described below. Furthermore, also with respect to the SEM images even after high-temperature storage, it is possible to form the transparent electrode 2 having a stable film quality and a uniform thickness although the transparent electrode has a small thickness, without spreading fine defective portions at the time of film deposition.

### (Film Deposition Method of Calcium-Containing Layer)

A film deposition method of the above calcium-containing layer 1 is not particularly limited, but from the viewpoint of stabilizing the film quality of the transparent electrode 2, and suppressing the damage to the light-emitting unit 3, there is preferably applied a dry process such as a vapor deposition method (resistance heating, EB method, and the like).

### <Transparent Electrode 2>

The transparent electrode 2 is a layer that is composed of silver as a main component, and is constituted by using silver or an alloy containing silver as a main component, and is provided adjacent to the calcium-containing layer 1.

The transparent electrode 2 is preferably a layer composed of silver or an alloy containing silver (Ag) as a main component, from the viewpoint of small inherent absorption and large electric conductivity. The alloy containing silver (Ag) as a main component which constitutes the transparent electrode 2 is preferably an alloy containing silver in an amount of 50% by mass or more. Examples of the alloys containing silver (Ag) as a main component include, for example, silver magnesium (AgMg), silver copper (AgCu), silver palladium (AgPd), silver copper palladium (AgPdCu), silver indium (AgIn), silver aluminum (AgAl), silver gold (AgAu), and the like.

The above transparent electrode 2 may have a laminated configuration in which layers of silver or an alloy containing silver as a main component are laminated by being divided into a plurality of layers as necessary.

A thickness of the transparent electrode 2 is preferably set within the range of 6 to 20 nm, more preferably set to be 6 to 15 nm. When the thickness of the transparent electrode 2 is set to be 6 nm or more, the electrical conductivity of the transparent electrode 2 is sufficiently ensured. Furthermore, when the thickness of the transparent electrode 2 set to be 20 nm or less, an absorption component or a reflection component of the transparent electrode 2 is suppressed at a low level, and the light emission efficiency of the organic EL element 10 is maintained, thereby being preferable. Furthermore, when the thickness of the transparent electrode 2 is set to be 15 nm or less, the light emission efficiency of the organic EL element 10 is further enhanced, thereby being preferable.

Namely, a film deposition state of the transparent electrode 2 having the above-described thickness is excellent as shown in the SEM images of Examples described below. Furthermore, even in the SEM images after storage at a high temperature, there is obtained a film having a uniform thickness and a stable film quality although the transparent electrode has a small thickness, without spreading fine defective portions at the time of film deposition.

In addition, in order not to inhibit the light emission efficiency of the organic EL element 10, it is preferable to set the thickness of the transparent electrode 2 so that the total thickness of the transparent electrode 2 and the calcium-containing layer 1 is 22 nm or less, and the total thickness is particularly preferably 17 nm or less. When the total thickness of the transparent electrode 2 and the calcium-containing layer 1 is set to be 22 nm or less, the absorption component and the reflection component of the two layers are suppressed at a low level, and the light emission efficiency of the organic EL element 10 is maintained, thereby being preferable. Furthermore, particularly when the total thickness of the transparent electrode 2 and the calcium-containing layer 1 is set to be 17 nm or less, the light emission efficiency of the organic EL element 10 can be further enhanced, thereby being preferable.

Moreover, a ratio of thickness between the transparent electrode 2 and the calcium-containing layer 1 is preferably within the range of 10:1 to 30:1. Accordingly, the calcium (Ca) atom in the calcium-containing layer 1 and the silver (Ag) atom in the transparent electrode 2 further easily interact with each other.

### (Film Deposition Method of Transparent Electrode)

Examples of the film deposition methods of the above transparent electrode 2 include: a method using a wet process such as an application method, an inkjet method, a coating method or a dipping method; a method using a dry process such as a vapor deposition method (resistance heating, EB method, and the like), a sputtering method or a CVD method, and the like. Here, from the viewpoint of suppressing damage to the organic layers constituting the light-emitting unit 3, there is preferably applied the dry process such as a vapor deposition method (resistance heating, EB method, and the like).

Here, for example, in a case where there is film-deposited the transparent electrode 2 by application of the sputtering method, a sputtering target of an alloy containing silver as a main component is prepared, and sputtering film deposition using the sputtering target is performed. In all cases of the above alloys, the transparent electrode 2 is film-deposited by application of the sputtering method, and particularly in a case of film deposition of a silver copper (AgCu), a silver palladium (AgPd), or a silver palladium copper (AgPdCu), the film deposition of the transparent electrode 2 is carried out by applying the sputtering method.

Furthermore, particularly in case of film deposition of a silver aluminum (AgAl), a silver magnesium (AgMg), or a silver indium (AgIn), the film deposition of the transparent electrode 2 is preferably carried out by application of the vapor deposition method. In case of the vapor deposition method, the alloy component and silver (Ag) are codeposited. At this time, there is carried out the vapor deposition film-formation in which an addition concentration of the alloy component relative to the silver (Ag) as a main material is adjusted by adjustment of the vapor vapor-deposition rate of the alloy component and the vapor vapor-deposition rate of the silver (Ag).

Moreover, the transparent electrode 2 has the feature of having a sufficient conductivity even without a high-temperature annealing treatment or the like after the film deposition, by the film deposition onto the calcium-containing layer 1, and the high-temperature annealing treatment or the like may be carried out after the film deposition, as necessary.

### <Other Constituent Elements>

The above organic EL element 10 may be provided with the following auxiliary electrode in contact with the transparent electrode 2, in order to achieve the lowering of the resistance of the transparent electrode 2 which is on a light extraction side. Furthermore, in order to prevent degradation of the light-emitting unit 3 constituted by the use of the organic materials or the like, the unit is sealed with the following sealing member on the substrate 11. Moreover, the following protective film or protective plate may be provided between the substrate 11 by sandwiching the organic EL element 10 and the sealing member.

### [Auxiliary Electrode]

An auxiliary electrode is provided in order to lower an electric resistance of an electrode having a light-transmitting property (here, for example, the transparent electrode 2) and is provided in contact with the transparent conductor 2. A metal having a low electric resistance such as gold, platinum, silver, copper or aluminum is preferable as a material that forms the auxiliary electrode. Since these metals have a low light-transmitting property, a pattern is formed within a range not influencing the extraction of the emitted light h from a light extraction surface. Examples of methods of forming the auxiliary electrode include a vapor deposition method, a sputtering method, a printing method, an inkjet method, an aerosol jet method, and the like. It is preferable that the line width of the auxiliary electrode is 50 μm or less from the viewpont of a light-extraction aperture ratio, and the thickness of the auxiliary electrode is 1μ or more from the viewpont of electric conductivity.

Note that the auxiliary electrode may be provided in contact with the counter electrode 5 as necessary.

### [Sealing Member]

A sealing member is a material covering the organic EL element 10, and may be a plate-like (film-like) sealing member which is fixed to the substrate 11 side by an adhesive, or may be a sealing film. However, the terminal parts of the transparent electrode 2 and the counter electrode 5 are provided in a state of being exposed from the sealing member in such a manner that the electric insulation may be kept by the light-emitting unit 3 on the substrate 11 to each other. Furthermore, since the surface of the sealing member serves as a light extraction surface where the emitted light h of the organic EL element 10 is extracted, a material having a light-transmitting property is used.

Examples of the plate-like (film-like) sealing member include, for example, a glass substrate, a polymer substrate, and these substrate materials may be used further in the form of thin film.

Examples of the glass substrates can include particularly soda lime glass, barium strontium-containing glass, lead glass, alminosilicate glass, borosilicate glass, barium borosilicate glass, quartz, and the like. In addition, examples of the polymer substrates can include polycarbonate, acryl, polyethylene terephthalate, polyethersulfide, polysulfone, and the like.

Among them, from the viewpoint of being capable of making the element thinner, polymer substrate or metal material substrate, in the form having a small thickness, is preferably used as the sealing member.

The film-like polymer substrate preferably has an oxygen permeability measured by the method in accordance with JIS-K-7126-1987 of 1×10⁻³ ml/(m²·24 hr·atm) or less and a water vapor permeability (25±0.5° C., relative humidity (90±2)% RH) measured by the method in accordance with JIS-K-7129-1992 of 1×10⁻³ g/(m²·24 hr) or less.

Moreover, the above substrate material may be processed in the form of concave plate and be used as the transparent sealing member. In such a case, processing such as sandblast processing or chemical etching processing is performed on the above substrate member to thereby form concave portions.

Moreover, the adhesive for fixing the plate-like sealing member to the substrate 11 side is used as a sealant for sealing the organic EL element 10 sandwiched between the sealing member and the substrate 11. Specific examples of the adhesives can include a photo curable and thermosetting-type adhesive having a reactive vinyl group of an acrylic acid-based oligomer or methacrylic acid-based oligomer, a moisture curable-type adhesive such as 2-cyanoacrylic acid ester, and the like.

In addition, examples of the adhesives can include a thermosetting or chemical curable-type (two liquids mixing type) adhesive such as epoxy-based adhesive. Furthermore, there can be included a hot-melt-type polyamide, polyester, and polyolefin. Moreover, there can be included an ultraviolet curable-type epoxy resin adhesive of cationic curable type.

Note that there is a case where the organic materials constituting the organic EL element 10 is degraded through heat treatment. Accordingly, it is preferable that an adhesive is adherable and curable from room temperature to 80° C. In addition, a drying agent may be dispersed in the adhesive.

Coating of the adhesive on the adhesion portion of the sealing member and the substrate 11 may be carried out by the use of a commercially available dispenser, or by printing such as screen-printing.

Moreover, when a gap is formed among the plate-like sealing member, the substrate 11 and the adhesive, it is preferable to inject an inert gas such as nitrogen or argon, or an inert liquid such as a fluorinated hydrocarbon or a silicone oil, into the gap, in a case of gaseous phase and liquid phase. It is also possible to make vacuum. Furthermore, it is possible to encapsulate a hydroscopic compound into the gap.

Examples of the hydroscopic compounds include, for instance, a metal oxide (for example, sodium oxide, potassium oxide, calcium oxide, barium oxide, magnesium oxide, aluminum oxide, etc.), a sulfate (for example, sodium sulfate, calcium sulfate, magnesium sulfate, cobalt sulfate, etc.), a metal halide (for example, calcium chloride, magnesium chloride, cesium fluoride, tantalum fluoride, cesium brominate, magnesium brominate, barium iodide, magnesium iodide, etc.), a perchloric acid (for example, barium perchloric acid salt, magnesium perchloric acid salt, etc.), and the like. An anhydrous salt is suitably used in the sulfate, metal halide and the perchloric acid.

On the other hand, when the sealing film is used as the sealing member, the sealing film is formed on the substrate 11 in a state where the light-emitting unit 3 in the organic EL element 10 is completely covered and the terminal parts of the transparent electrode 2 and the counter electrode 5 of the organic EL element 10 are exposed.

The sealing film is constituted by the use of an inorganic material or an organic material. Particularly, the sealing film is constituted by a material having function of suppressing the intrusion of a substance that causes degradation of the light-emitting unit 3 in the organic EL element 10, such as moisture and oxygen. Examples of such materials that can be used include inorganic materials such as silicon oxide, silicon dioxide and silicon nitride. In order to further improve its fragility of the sealing film, a laminated structure may be formed by the use of a film made of an organic material in addition to the film made of the inorganic material.

The method for forming the films is not particularly limited, and there can be used, for example, a vacuum deposition method, a sputtering method, a reactive sputtering method, a molecular beam epitaxy method, a cluster ion beam method, an ion plating method, a plasma polymerization method, an atmospheric pressure plasma polymerization method, a plasma CVD method, a laser CVD method, a thermal CVD method, a coating method, and the like.

Note that the above-described sealing member may further have an electrode, and the member may be constituted such that the terminal parts of the transparent electrode 2 and the counter electrode 5 of the organic EL element 10 is electrically conducted with the electrode.

### [Protective Layer, Protective Plate]

A protective layer or a protective plate is to mechanically protect the organic EL element 10, and particularly in a case where a sealing member is a sealing film, it is preferable to provide the protective layer or the protective plate since the mechanical protection of the organic EL element 10 is not sufficient.

The protective layer or the protective plate as described above is constituted of a material having a light-transmitting property and the examples thereof include a glass plate, a polymer plate, a polymer film thinner than a glass plate or a polymer plate, or a polymer material film. Among them, the polymer film is preferably used from the viewpoint of light weight and small thickness.

### <Method for Production of Organic EL Element>

The production of the above-described organic EL element 10 can be carried out in the following way.

First, the counter electrode 5 is formed as an anode on the substrate 11. The counter electrode 5 is formed by the use of an appropriate film deposition method such as a vapor deposition method or a sputtering method. Furthermore, in the film deposition of the counter electrode 5, the counter electrode 5 is formed in a shape in which a terminal portion is pulled out from the peripheral of the substrate 11, by the film deposition using, for example, a mask as necessary.

Next, the light-emitting unit 3 including the light-emitting layer is deposited on the counter electrode 5. Each layer constituting the light-emitting unit 3 is deposited by application of an appropriately selected film deposition method. Moreover, in the film deposition of respective layers constituting the light-emitting unit 3, the respective layers constituting the light-emitting unit 3 are formed in a shape in which a terminal portion of the counter electrode 5 is exposed, by the film deposition using, for example, a mask as necessary.

Next, the calcium-containing layer 1 is formed on the light-emitting unit 3 so as to have a thickness of 2 nm or less. Subsequently, the transparent electrode 2 composed of silver (or an alloy containing silver as a main component) is formed as a cathode so as to have a thickness of 6 nm to 20 nm. In the above film deposition, the above-described vapor deposition method is applied. Furthermore, in the film deposition of the transparent electrode 2, the transparent electrode 2 is formed in a shape in which a terminal portion of the transparent electrode 2 is pulled out from the peripheral of the substrate 11 while maintaining an electric insulation state between the transparent electrode and the counter electrode 5 by the light-emitting unit 3, by the film deposition using, for example, a mask as necessary.

From the above procedures, there is obtained the top-emission type organic EL element 10 in which the emitted light is extracted from the reverse side of the substrate 11. In addition, thereafter, there is provided the sealing member that covers at least the light-emitting unit 3 in a state where the terminal portions of the transparent electrode 2 and the counter electrode 5 in the organic EL element 10 are exposed. At this time, the sealing member is caused to adhere to the substrate 11 side by the use of an adhesive, and the light-emitting unit 3 of the organic EL element 10 is sealed between the sealing member and the substrate 11.

### <Effect>

The organic EL element 10 described above has the configuration in which the calcium-containing layer 1 is provided adjacent to the transparent electrode 2 between the transparent electrode 2 and the light-emitting unit 3. This calcium-containing layer 1 can enhance a moving speed of an electron injected from the transparent electrode 2. Thereby, in the organic EL element 10, it is possible to alleviate an electron injection barrier due to a high work function of the silver, and thus to cause the silver electride having a small thickness constituting the transparent electrode 2 to function as a cathode.

Furthermore, as shown in the following Examples, in comparison with an organic EL element having no calcium-containing layer 1, enhancement of the light emission efficiency is achieved along with decrease in the driving voltage.

In addition, particularly, as shown in the SEM images of Examples described below, a film deposition state of the transparent electrode 2 containing silver as a main component is excellent, and further, even in the SEM images after storage at a high temperature, it is possible to form the transparent electrode 2 having a stable film quality and a uniform thickness although the transparent electrode has a small thickness, without spreading fine defective portions at the time of film deposition.

Namely, according to the above configuration, in depositing the transparent electrode 2 on the calcium-containing layer 1, the silver or the silver alloy constituting the transparent electrode 2 interacts with each other at an interface of the calcium-containing layer 1 to thereby reduce distance of surface diffusion, which results in suppressing agglomeration. That is, since the number of nuclei (growth nuclei) for making the film of the transparent electrode 2 grow is more increased than usual, it is possible to form a continuous film having a uniform thickness although the transparent electrode has a small thickness, from the growth nucleus as a starting point.

Furthermore, since the calcium (Ca) constituting the calcium-containing layer 1 and the silver or the silver alloy constituting the transparent electrode 2 interacts with each other, migration of the silver atom is suppressed, and thus, for example, the transparent electrode 2 has a stable film quality even by the external heating.

Therefore, the organic EL element 10 of the present embodiment can cause the silver electride having a small thickness constituting the transparent electrode 2 to function as a cathode, and there is formed the transparent electrode 2 having a stable film quality and a uniform thickness although the transparent electrode has a small thickness, with the result that enhancement of the light emission efficiency is achieved and also prolongation of the life is achieved, along with the decrease in the driving voltage.

### <<1-1. Modification of Organic EL Element>>

### (Bottom-Emission Type)

FIG. 2 is a schematic cross-sectional view showing the configuration of a modification of the organic EL element according to the first embodiment of the present invention. As shown in FIG. 2, an organic EL element 10′ is different from the organic EL element 10 shown in FIG. 1 only in that the element has a configuration of the bottom emission type in which the transparent electrode 2 is provided at the substrate 11 side and light is extracted from the substrate 11 side. Accordingly, the similar symbol is attached to the similar configuration to that in the organic EL element 10 shown in FIG. 1, and thus the overlapped explanation will be omitted.

The organic EL element 10′ shown in FIG. 2 has a configuration in which, for example, the transparent electrode 2, the calcium-containing layer 1, the light-emitting unit 3 and the counter electrode 5 are provided on one main surface of the substrate 11, in this order. In addition, also in the present embodiment, the features are that the calcium-containing layer 1 is provided adjacent to the transparent electrode 2 between the transparent electrode 2 and the light-emitting unit 3, and the transparent electrode 2 is used as a cathode and the counter electrode 5 is used as an anode.

Note that the layer structure of this organic EL element 10′ is not limited, and may be a general layer structure. Furthermore, the organic EL element 10′ has a configuration in which the sealing member that seals the light-emitting unit 3 is provided on the main side of the substrate 11, although not being illustrated in the Figure; and further the protective film and the like may be provided, and the auxiliary electrode may be provided in contact with the electrode. Moreover, there is provided an underlayer for improving the film quality of the transparent electrode 2, under the transparent electrode 2, namely, between the transparent electrode 2 and the substrate 11.

### <Underlayer>

The underlayer is a layer provided between the substrate 11 and the transparent electrode 2. This underlayer is, for example, a layer not only for improving the smoothness, film quality and conductivity of the transparent electrode 2, but also for enhancing the light-transmitting property, and is preferably provided adjacent to the transparent electrode 2.

Such an underlayer is not particularly limited as long as the above-mentioned purpose is accomplished, and is able to be appropriately selected according to the purpose. The underlayer may have a structure laminated with a layer that adjusts the light-transmitting property (optical admittance) of the transparent electrode 2 by being constituted of a layer having a high refractive index or a low refractive index.

Furthermore, the underlayer may have the above calcium-containing layer 1. In this case, the similar material to that of the calcium-containing layer 1 shown in FIG. 1 is used in the calcium-containing layer, and for example, the two calcium-containing layers arranged so as to sandwich the transparent electrode 2 may have the similar configuration or may have different configurations from each other. Moreover, the two calcium-containing layers arranged so as to sandwich the transparent electrode 2 may have the same thickness or different thicknesses, and the thickness of the calcium-containing layer formed as the underlayer of the transparent electrode 2 is preferably within the range of 2.0 nm or less, more preferably within the range of 0.5 to 2.0 nm. When forming the calcium-containing layer so as to have a thickness of such a range, it is possible to form the transparent electrode 2 on the calcium-containing layer so as to have a uniform thickness and stable film quality although the electrode 2 has a small thickness.

For example, a light-adjusting layer is preferably provided as the underlayer from the viewpoint of enhancing the light-transmitting property of the transparent electrode 2 by adjusting optical properties such as a reflectivity and permeability of the transparent electrode 2. The light-adjusting layer may be composed of a material having a different refractive index relative to the substrate 11 having a light-transmitting property, and a high-refractive-index layer mainly having a refractive index higher than that of the substrate 11 is used as the light-adjusting layer. The refractive index of the high-refractive-index layer is preferably higher than the refractive index of the substrate 11 by 0.1 to 1.1 or more, more preferably higher than the refractive index of the substrate 11 by 0.4 to 1.0 or more. The refractive index of the high-refractive-index layer is a refractive index of light having a wavelength of 510 nm, and is measured by, for example, an ellipsometer.

Note that, although the material exemplified as the sealing member of the organic EL element 10 shown in FIG. 1 is used, in the same way, as the sealing member that covers the modification of the organic EL element 10′, the sealing member that covers the counter electrode 5 side may not have a light-transmitting property since the organic EL element 10′ has a construction of extracting the emitted light h from the substrate 11 side. Therefore, the sealing member may be constituted by, for example, a metal material substrate. Examples of the metal material substrates include: one or more of kinds of metals selected from the group consisting of stainless steel, iron, copper, aluminum, magnesium, nickel, zinc, chromium, titanium, molybdenum, silicon, germanium and tantalum; or an alloy thereof.

In addition, the above-described materials can be used, in the same way, as a protective film or protective substrate, and, for example, a thin metal plate, metal film, or the like may be provided.

### <Effect>

The organic EL element 10′ constituted as above has a configuration of the bottom-emission type in which the transparent electrode 2 is provided on the substrate 11 side, and the emitted light is extracted from the substrate 11 side, and also has a configuration in which the calcium-containing layer 1 is provided adjacent to the transparent electrode 2 between the transparent electrode 2 and the light-emitting unit 3.

Thereby, in the same way as the results in the first embodiment, according to the organic EL element 10′, the silver electride having a small thickness constituting the transparent electrode 2 can function as a cathode.

Furthermore, for example, when providing the light-adjusting layer as the underlayer of the transparent electrode 2, it becomes possible to adjust the reflectivity, the permeability and the like of the transparent electrode 2, and to thereby reduce absorption inherent to the metal material. Namely, since it becomes possible to adjust the optical admittance of the transparent electrode 2 in accordance with a medium on the side where the light of the transparent electrode 2 enters, and to thereby prevent the reflection at the interface with the medium. Thereby, the organic EL element 10′ achieves enhancement of the light emission efficiency along with the decrease in the driving voltage. Furthermore, when a plurality of the light-adjusting layers is used, the freedom of design range is enhanced since there is expanded the range in which the optical admittance of the transparent electrode 2 can be optimized.

Moreover, for example, when the calcium-containing layer as the underlayer of the transparent electrode 2 is provided, the similar effects to those in the first embodiment are obtained.

Note that the organic EL element 10′ of the modification described above may have the stack structure in combination with the organic EL element 10 shown in FIG. 1. In this case, for example, the configuration is such that the counter electrode 5 of the organic EL element 10′ shown in FIG. 2 is used as an intermediate electrode, and furthermore, the light-emitting unit 3, the calcium-containing layer 1 and the transparent electrode 2 are laminated above the counter electrode 5 in this order. Even in such a configuration, the two transparent electrodes 2 composed of silver as a main component are used as a cathode, and the counter electrode 5 is used as an anode.

### 2. Second Embodiment: Organic EL Element Having Stack Structure

(Example in which Transparent Electrode is Provided Between Two Light-Emitting Units)

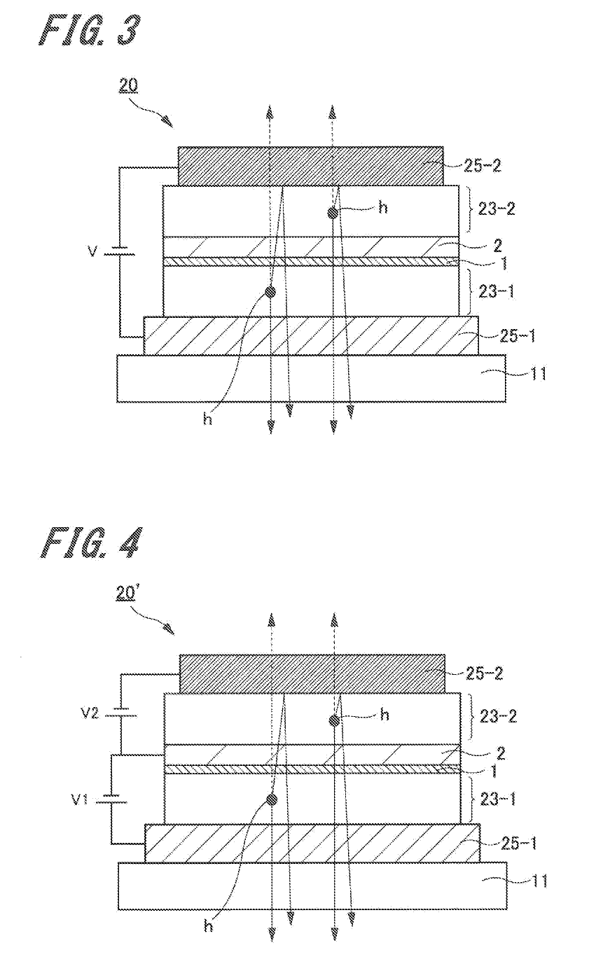

FIG. 3 is a schematic cross-sectional view showing the configuration of the organic EL element (stack structure) according to the second embodiment of the present invention. As shown in FIG. 3, an organic EL element 20 is different from the organic EL element 10 shown in FIG. 1 only in that the element has a configuration of the stack structure in which the light-emitting unit and the counter electrode are further laminated on one main surface of the transparent electrode 2. Accordingly, the similar configuration to that in the organic EL element 10 shown in FIG. 1 is indicated by the same symbol, and thus the overlapped explanation is omitted.

Namely, the organic EL element 20 shown in FIG. 3 has a configuration in which, for example, a first counter electrode 25-1, a first light-emitting unit 23-1, the calcium-containing layer 1, the transparent electrode 2, a second light-emitting unit 23-2 and a second counter electrode 25-2 are provided in this order, on one main surface of the substrate 11.

In the present embodiment, the features are that the calcium-containing layer 1 is provided adjacent to the transparent electrode 2 between the transparent electrode 2 and the first light-emitting unit 23-1. Furthermore, the first counter electrode 25-1 is used as an anode, and the second counter electrode 25-2 is used as a cathode.

Moreover, according to the present embodiment, there will be described the configuration of the organic EL element having a bottom-emission structure in which the generated light is extracted from at least the substrate 11 side.

Hereinafter, each of main layers constituting the above organic EL element 20 will be described in detail in the order of the first counter electrode 25-1, the first light-emitting unit 23-1, the calcium-containing layer 1, the transparent electrode 2, the second light-emitting unit 23-2 and the second counter electrode 25-2.

### <First Counter Electrode 25-1>

The first counter electrode 25-1 is similar to the counter electrode 5 of the present invention described above, and is used as an anode for supplying a positive hole to the first light-emitting unit 23-1 of the organic EL element 20.

In addition, the first counter electrode 25-1 is an electrode provided on the side where the emitted light h generated in the light-emitting unit is extracted, and is composed of a material having a light-transmitting property among the materials constituting the counter electrode 5 described above.

### <First Light-Emitting Unit 23-1>

The first light-emitting unit 23-1 is similar to the light-emitting unit 3 of the present invention described above, and has a configuration in which, for example, the [positive hole-injecting layer/positive hole transport layer/light-emitting layer/electron transport layer/electron-injecting layer] are laminated in this order from the first counter electrode 25-1 used as an anode, but the layers other than the light-emitting layer are provided as necessary.

### <Calcium-Containing Layer 1, Transparent Electrode 2>

The calcium-containing layer 1 and the transparent electrode 2 have the same configurations as described above, and, for example, the calcium-containing layer 1 is provided adjacent to the transparent electrode 2 between the transparent electrode 2 and the first light-emitting unit 23-1. Furthermore, the transparent electrode 2 functions as a cathode relative to the first light-emitting unit 23-1 of the organic EL element 20, and on the other hand, functions as an anode relative to the second light-emitting unit 23-2.

### <Second Light-Emitting Unit 23-2>

The second light-emitting unit 23-2 is a light-emitting unit sandwiched between the transparent electrode 2 and the second counter electrode 25-2, and has a configuration in which, for example, the [positive hole-injecting layer/positive hole transport layer/light-emitting layer/electron transport layer/electron-injecting layer] are laminated in this order from the transparent electrode 2 side which functions as an anode relative to the second light-emitting unit 23-2, but the layers other than the light-emitting layer are provided as necessary.

Note that the configuration of the second light-emitting unit 23-2 may be similar to or different from that of the first light-emitting unit 23-1. Furthermore, the second light-emitting unit may be configured so as to obtain the similar emitted light h to that or the different emitted light h from that of the first light-emitting unit 23-1.

### <Second Counter Electrode 25-2>

The second counter electrode 25-2 is an electrode which is arranged so as to face the transparent electrode 2 on an opposite side of the first counter electrode 25-1, and is used as a cathode for supplying an electron to the second light-emitting unit 23-2 of the organic EL element 20.

Furthermore, the second counter electrode 25-2 is, for example, an electrode that reflects, to the substrate 11 side, the emitted light h generated in the light-emitting layer of the light-emitting unit, and is composed of a reflective material.

The above-described second counter electrode 25-2 constituting the cathode is as follows.

An electrode material composed of a metal (referred to as an electron-injecting metal) having a small work function (4 eV or less), an alloy, an electrically conductive compound, or a mixture thereof is used as the second counter electrode 25-2 constituting the cathode. Specific examples of the electrode materials include sodium, a sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, aluminum, and a rare earth metal, and the like.

Among them, from the viewpoint of electron injection property and durability against oxidation or the like, preferred examples are mixtures of the electron-injecting metal and a secondary metal that has a work function higher than that of the electron-injecting metal and that is more stable, such as: a magnesium/silver mixture, a magnesium/aluminum mixture, a magnesium/indium mixture, an aluminum/aluminum oxide (Al₂O₃) mixture, and a lithium/aluminum mixture; aluminum and the like.

In the cathode, the electrode material can be produced by a method such as vapor deposition or sputtering of the electrode material. Furthermore, a sheet resistance of the cathode is preferably several hundred Q/square or less.

A thickness of the cathode is selected in consideration of permeability or reflectance, usually within the range of 10 nm to 5 μm, preferably within the range of 50 nm to 200 nm, although depending on the materials.

Note that a permeable material may be combined with the organic EL element 10 shown in FIG. 1 when the second counter electrode 25-2 used as the cathode is constituted of the permeable material. In such a case, the configuration is such that, for example, the calcium-containing layer 1 and the transparent electrode 2 are laminated in this order above the second light-emitting unit 23-2 of the organic EL element 20 shown in FIG. 3, and the transparent electrode 2 is used as the cathode relative to the second light-emitting unit 23-2.

The above cathode may be produced by a method such as vapor deposition or sputtering of the selected electrode material.

In driving the organic EL element 20 thus obtained, in a case of applying a direct voltage as a driving voltage V to the organic EL element 20, light emission can be observed when a voltage of approximately 2 V or more and 40 V or less is applied to the electrodes while the first counter electrode 25-1 of the anode is set as + polarity and the second counter electrode 25-2 of the cathode is set as − polarity. Furthermore, an alternating voltage may be applied to the first counter electrode 25-1 and the second counter electrode 25-2. Note that a waveform of the alternating voltage to be applied may be arbitrary

### <Effect>

The organic EL element 20 constituted as above has a configuration of a stack structure in which two light-emitting units are laminated, and the calcium-containing layer 1 is provided adjacent to the transparent electrode 2 between the transparent electrode 2 and the first light-emitting unit 23-1. Thereby, the organic EL element 20 can cause the silver electride having a small thickness constituting the transparent electrode 2 to function as a cathode relative to the first light-emitting unit 23-1, in the same way as the effect of the first embodiment.

On the other hand, the silver electride having a small thickness constituting the transparent electrode 2 can be preferably used as the anode due to a large work function of the silver, and thus can function as the anode relative to the second light-emitting unit 23-2.

Therefore, the organic EL element 20 can sufficiently inject an electron or positive hole from the transparent electrode 2 to the first light-emitting unit 23-1 and the second light-emitting unit 23-2, respectively, and thus the light emission efficiency can be enhanced.

Furthermore, since the configuration is such that the transparent electrode 2 is formed on the calcium-containing layer 1, there is formed the transparent electrode 2 having a stable film quality and a uniform thickness although the electrode 2 has a small thickness, in the same way as the effects of the first embodiment. Accordingly, in a case where the transparent electrode 2 is provided between the light-emitting units, the absorption of the light emitted from each light-emitting unit, in the transparent electrode 2, is suppressed, the light emission efficiency is enhanced, and the life is prolonged.

### <<2-1. Modification 1 of Organic EL Element>>

FIG. 4 is a schematic cross-sectional view showing the configuration of Modification 1 of the organic EL element according to the second embodiment of the present invention. As shown in FIG. 4, an organic EL element 20′ is different from the organic EL element 20 shown in FIG. 3 only in that the driving voltage is applied not only to the first counter electrode 25-1 and the second counter electrode 25-2 but also to the transparent electrode 2. Namely, since the configuration of Modification 1 is similar to that of the organic EL element 20 shown in FIG. 3, the overlapped explanation will be omitted.

In such a case, in driving the organic EL element 20′, a voltage applied between the first counter electrode 25-1 and the transparent electrode 2 is assumed to be a driving voltage V1, and a voltage applied between the transparent electrode 2 and the second counter electrode 25-2 is assumed to be a driving voltage V2. In a case of applying a direct voltage to the organic EL element 20′, the first counter electrode 25-1 of the anode is set as + polarity, and the second counter electrode 25-2 of the cathode is set as − polarity, a voltage of approximately 2 V or more and 40 V or less is applied, and an intermediate voltage between the anode and the cathode is further applied to the transparent electrode 2.

Furthermore, when driving the organic EL element 20′, a duty drive may be caused to be performed. Moreover, the first light-emitting unit 23-1 and the second light-emitting unit 23-2 may be individually driven in combination with a switching circuit. At that time, there is provided a switch for switching the drive of the first counter electrode 25-1, the second counter electrode 25-2, and the transparent electrode 2, at a driving circuit portion for driving the organic EL element 20′. According to the organic EL element 20′ having such a configuration, it is possible to arbitrarily control, by switching of the switch, the drive of the first counter electrode 25-1 and the transparent electrode 2, or the drive of the second counter electrode 25-2 and the transparent electrode 2, and thus it is possible to emit light by arbitrarily selecting the first light-emitting unit 23-1 and the second light-emitting unit 23-2.

Moreover, in a case where the first light-emitting unit 23-1 and the second light-emitting unit 23-2 emit the emitted lights h having different colors, it is possible to constitute a color-matchable organic EL element 20′ by arbitrarily causing these light-emitting units to perform duty drive.

### <Effect>

According to the organic EL element 20′ constituted as described above, it is possible to arbitrarily change the proportion of the lights emitted in the first light-emitting unit 23-1, the second light-emitting unit 23-2 in addition to the effects in the second embodiment by adjusting the intermediate voltage applied to the transparent electrode 2.

Therefore, in a case where each of the first light-emitting unit 23-1 and the second light-emitting unit 23-2 of the organic EL element 20′ is constituted such that the emitted light h having different colors is obtained, the control of color light emission by controlling the proportion of the emitted light becomes also possible.

### <<2-2. Modification 2 of Organic EL Element>>

FIG. 5 is a schematic cross-sectional view showing the configuration of Modification 2 of the organic EL element according to the second embodiment of the present invention. As shown in FIG. 5, an organic EL element 20″ has a configuration in which the first counter electrode 25-1 and the second counter electrode 25-2 are set as + polarity and a driving voltage of − polarity is applied to the transparent electrode 2, and is different from the organic EL element 20 shown in FIG. 3 only in that a calcium-containing layer 1″ is provided between the transparent electrode 2 and a second light-emitting unit 23-2″, and in that the second light-emitting unit 23-2″ is reversely laminated. Accordingly, the similar symbol is attached to the similar configuration to that in the organic EL element 20 shown in FIG. 3, and thus the overlapped explanation will be omitted.

Namely, the organic EL element 20″ shown in FIG. 5 has a configuration in which, for example, the first counter electrode 25-1, the first light-emitting unit 23-1, the calcium-containing layer 1, the transparent electrode 2, the calcium-containing layer 1″, the second light-emitting unit 23-2″ and the second counter electrode 25-2 are provided in this order, on one main surface of the substrate 11.

In Modification 2, the features are that the calcium-containing layer 1″ is provided adjacent to the transparent electrode 2 between the transparent electrode 2 and the second light-emitting unit 23-2″, and the transparent electrode 2 is used as a cathode with respect to the first counter electrode 25-1 and the second counter electrode 25-2, and the first counter electrode 25-1 and the second counter electrode 25-2 are used as an anode.

### <Calcium-Containing Layer 1″>

The calcium-containing layer 1″ is similar to the calcium-containing layer 1 of the present invention as described above, and is provided adjacent to the transparent electrode 2 between the transparent electrode 2 and the second light-emitting unit 23-2″.

Note that the similar material to that of the calcium-containing layer 1 shown in FIG. 1 is used for the calcium-containing layer 1″, and for example, the two calcium-containing layers which are arranged so as to sandwich the transparent electrode 2 may have a similar configuration or may have different configurations from each other.

For example, the two calcium-containing layers arranged so as to sandwich the transparent electrode 2 may be constituted so as to have the same thickness or different thicknesses, and at least of the thickness of the calcium-containing layer 1 serving as the underlayer of the transparent electrode 2 is, as described above, preferably within the range of 2.0 nm or less, more preferably within the range of 0.5 to 2.0 nm.

When forming the calcium-containing layer 1 in such a thickness range, it is possible to form the transparent electrode 2 on the calcium-containing layer 1 so as to have a uniform thickness and stable film quality although the electrode has a small thickness.

### <Second Light-Emitting Unit 23-2″>

The second light-emitting unit 23-2″ has a reversely laminated configuration of the above-described second light-emitting unit 23-2. Namely, the configuration is such that the [electron-injecting layer/electron transport layer/light-emitting layer/positive hole transport layer/positive hole-injecting layer] are laminated in this order from the transparent electrode 2 side. Note that the layers other than the light-emitting layer are arbitrarily provided as necessary.

Furthermore, the second light-emitting unit 23-2″ may have a configuration of the reversely laminated one similar to the first light-emitting unit 23-1 or may have a configuration different from that of the first light-emitting unit 23-1. Furthermore, the second light-emitting unit may be configured so as to obtain the emitted light h of the same color as that of the first light-emitting unit 23-1 or the emitted light h of different colors from that of the first light-emitting unit 23-1.

In driving the organic EL element 20″, in a case where a direct voltage is applied when a voltage applied between the first counter electrode 25-1 and the transparent electrode 2 is assumed to be a driving voltage V1, and a voltage applied between the transparent electrode 2 and the second counter electrode 25-2 is assumed to be a driving voltage V2, the first counter electrode 25-1 and the second counter electrode 25-2 of the anode are set as + polarity, and the transparent electrode 2 of the cathode is set as − polarity, light emission can be observed when a voltage of about 2 V or more and 40 V or less is applied. Moreover, an alternating voltage may be applied to the first counter electrode 25-1 and the second counter electrode 25-2, and the transparent electrode 2. Note that a waveform of the alternating voltage to be applied may be arbitrary.

Note that, in driving the organic EL element 20″, a duty drive may be caused to be performed in the similar way to that in above-described Modification 1. Thereby, also in the organic EL element 20″, it is possible to emit light by arbitrarily selecting the first light-emitting unit 23-1 and the second light-emitting unit 23-2. In addition, when the emitted lights h of the respective light-emitting units are different from each other, it is possible to constitute a color-matchable organic EL element 20″.

### <Effect>

The organic EL element 20″ constituted as above has a configuration in which the calcium-containing layer 1 and the calcium-containing layer 1″ are provided adjacent to the transparent electrode 2, respectively, between the transparent electrode 2 and the first light-emitting unit 23-1 and between the transparent electrode 2 and the second light-emitting unit 23-2″. Thereby, according to the organic EL element 20″, the silver electride having a small thickness constituting the transparent electrode 2 can function as a cathode with respect to the second counter electrode 25-2, in addition to the effects of the second embodiment.

Furthermore, in the similar way to the effects in above-described Modification 1, it becomes possible to arbitrarily change a light emission ratio in the first light-emitting unit 23-1 and the second light-emitting unit 23-2″ in addition to the effects in the second embodiment, by adjusting the intermediate voltage applied to the transparent electrode 2.

Therefore, in a case where each of the first light-emitting unit 23-1 and the second light-emitting unit 23-2″ of the organic EL element 20″ is constituted so as to give emitted light h of different colors, it is possible to control color light emission by controlling the light emission ratio.

Note that, although, in the organic EL element 20 of the present embodiment and the organic EL elements 20′ and 20″ of Modifications 1 and 2 described above, there has been explained the bottom emission structure in which the generated light is extracted at least from the substrate 11 side, the top-emission structure in which the emitted light h is extracted from an opposite side of the substrate 11 may be employed in the similar way to that in the organic EL element 10 of the first embodiment. In this case, the first counter electrode 25-1 is composed of a reflective material, and the second counter electrode 25-2 is composed of a material having light permeability.

Furthermore, there may also be constituted an organic EL element of a both-side emission type in which the emitted light h is also extracted from the second counter electrode 25-2 side. In this case, the second counter electrode 25-2 is composed of a material having light permeability.

In addition, although, in the organic EL element 20 of the present embodiment and the organic EL elements 20′ and 20″ of Modifications 1 and 2 described above, there is employed a stack structure in which two light-emitting units are laminated, there may be employed a stack structure in which, for example, three or more light-emitting units are laminated. In this case, the configuration of each light-emitting unit may be, for example, a configuration in which the calcium-containing layer 1 is provided between the transparent electrode and either one of the light-emitting units adjacent to the transparent electrode 2 in the similar way to that in the organic EL element 20 of the present embodiment, or may be a configuration in which the calcium-containing layer 1 is provided between the transparent electrode and the light-emitting unit adjacent to both sides of the transparent electrode 2, in the similar way to that in the organic EL element 20″ of Modification 2.

### 3. Third Embodiment: Use of Organic EL Element

The organic EL elements shown in FIGS. 1 to 5 can be applied as electronic devices such as display devices, displays, and various light emitting sources. Examples of the light-emitting sources include, but are not limited to, a lighting device such as a home lighting device or a car lighting device, a backlight for a timepiece or a liquid crystal, lighting for advertisement, a light source for a signal, alight source for an optical storage medium, a light source for an electrophotographic copier, a light source for an optical communication processor, a light source for an optical sensor. Particularly, the organic EL elements can be effectively used as a backlight for a liquid crystal display device which is combined with a color filter and as a light source for lighting.

Hereinafter, the present invention will be described specifically on the basis of the examples, but the present invention is not limited to the following examples.

### <<Production of Top-Emission-Type Organic EL Element>>

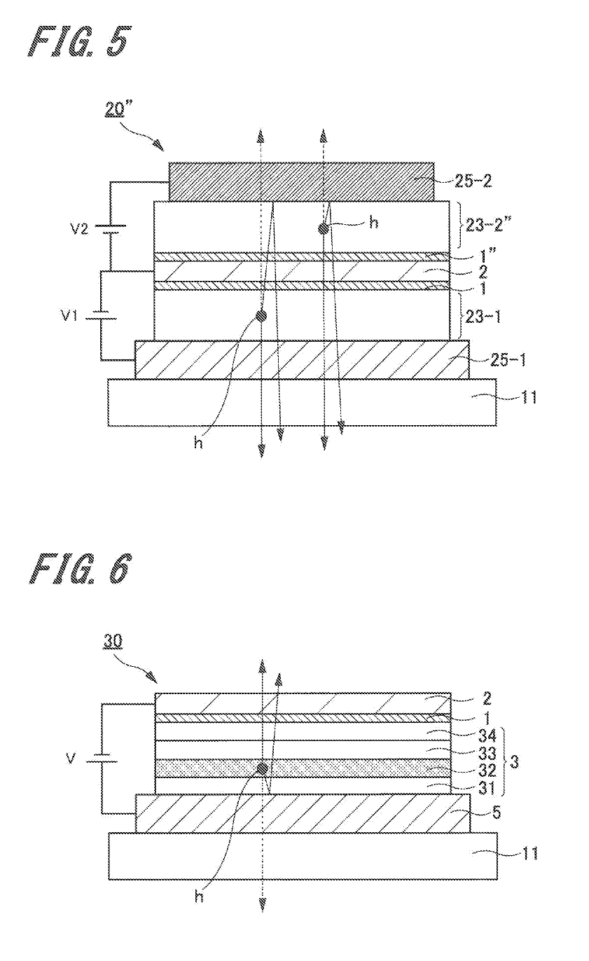

Each organic EL element 101 to 118 of the top-emission-type was produced so that an area of the light emitting region was 4.5 cm×4.5 cm. In the following Table 1, the main configuration of the organic EL element 101 to 118 is shown. The production procedures will be explained by referring to FIG. 6 and Table 1 below.

### <Production Procedures of Organic EL Element 101>

### [Production of Counter Electrode 5]

First, a glass substrate 11 (hereinafter referred to as substrate 11) was fixed onto a substrate holder of a commercial vacuum vapor-deposition apparatus, and was then transported into a vacuum tank of the vacuum vapor-deposition apparatus, and after reduction of a pressure of the vacuum tank to 4×10⁻⁴ Pa, the heating boat attached to the vacuum tank and containing aluminum was heated by applying an electric current. Thereby, a counter electrode 5 of aluminum having a thickness of 100 nm was formed at a vapor-deposition rate of 0.3 nm/sec. The counter electrode 5 is used as an anode.

### [Production of Light-Emitting Unit 3]

### (Positive Hole Transport/Injection Layer 31)

The heating boat containing an organic material A (α-NPD) represented by the following structural formula as a positive hole transport/injection material was heated by application of an electric current and there was then deposited, on the counter electrode 5, a positive hole transport/injection layer 31 made of α-NPD and having both roles of the positive hole transport layer and the positive hole-injecting layer. At this time, the vapor-deposition rate was 0.1 nm/sec. to 0.2 nm/sec., and a thickness was 20 nm.

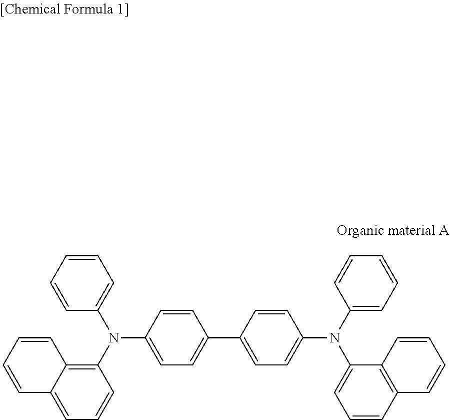 [SMILES: c1ccc(N(c2ccc(-c3ccc(N(c4ccccc4)c4cccc5ccccc45)cc3)cc2)c2cccc3ccccc23)cc1]

### (Light-Emitting Layer 32)

Next, an electric current was independently applied to each of the heating boat containing the host material H4 represented by the following structural formula and the heating boat containing the phosphorescence emitting compound Ir-4 represented by the following structural formula and there was then deposited, on the positive hole transport/injection layer 31, the light-emitting layer 32 composed of the host material H4 and the phosphorescence emitting compound Ir-4. At that time, the current to be applied to the heating boat was controlled so that the vapor-deposition rate of the host material H4:the phosphorescence emitting compound Ir-4 was equal to 100:6. Furthermore, the thickness of the light-emitting layer 32 was 30 nm.

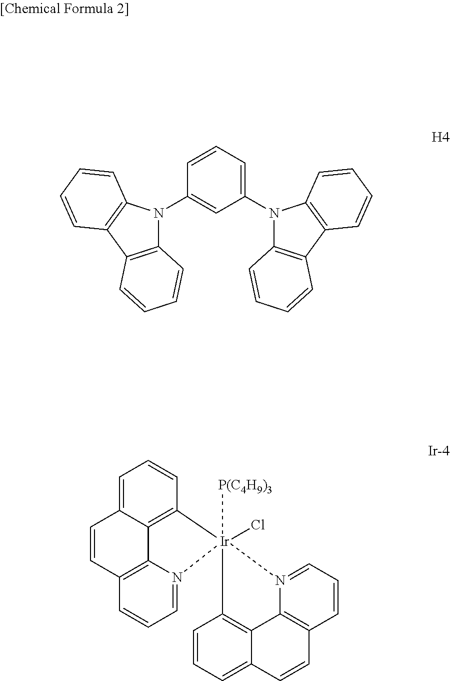

### (Positive Hole Blocking Layer 33)

Next, the heating boat containing BAlq represented by the following structural formula as a positive hole block material was heated by application of an electric current and there was then deposited, on the light-emitting layer 32, the positive hole blocking layer 33 made of BAlq. At this time, the vapor-deposition rate was 0.1 nm/sec. to 0.2 nm/sec., and a thickness was 10 nm.

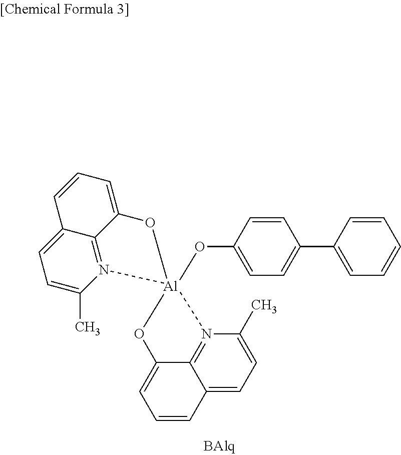

### (Electron Transport/Injection Layer 34)

After that, an electric current was independently applied to each of a heating boat containing an organic material B represented by the following structural formula as the electron transport injection material and a heating boat containing potassium fluoride and there was then deposited, on the positive hole blocking layer 33, the electron transport/injection layer 34 made of the organic material B and the potassium fluoride and having both roles of the electron-injecting layer and the electron transport layer. At this time, the current to be applied to the heating boat was controlled so that the vapor-deposition rate of the organic material B: the potassium fluoride was equal to 75:25.

In addition, the thickness was 30 nm.

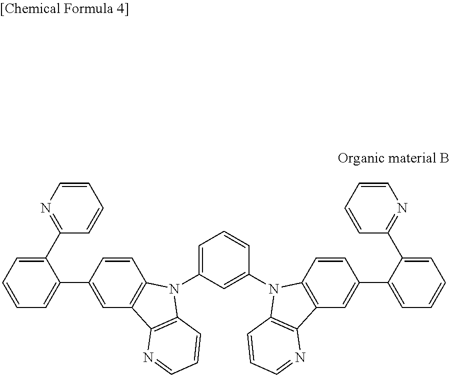 [SMILES: c1ccc(-c2ccccc2-c2ccc3c(c2)c2ncccc2n3-c2cccc(-n3c4ccc(-c5ccccc5-c5ccccn5)cc4c4ncccc43)c2)nc1]

### [Production of Transparent Electrode 2]

Subsequently, the substrate 11 on which the light-emitting unit 3 was formed was fixed onto a substrate holder of a commercial vacuum vapor-deposition apparatus, silver (Ag) was placed in a tungsten resistive heating boat, and then the substrate holder and the heating boat were attached to a vacuum tank. Next, after reduction of a pressure of the vacuum tank to 4×10⁻⁴ Pa, the heating boat was heated by application of an electric current, and a transparent electrode 2 made of silver (Ag) having a thickness of 10 nm was formed at a vapor-deposition rate of 0.1 nm/sec to 0.2 nm/sec. The transparent electrode 2 is used as a cathode.

### (Sealing of Element)

After that, the organic EL element 30 was covered by a sealing member (not shown in the drawing) of a glass substrate having a thickness of 300 μm, and an adhesive (sealing member) was filled into the space between the sealing member and the substrate 11 in a state where the organic EL element 30 was surrounded. An epoxy-based photocurable-type adhesive (Lackstrack LC0629B manufactured by TOAGOSEI) was used as the adhesive. The adhesive filled in the space between the sealing member and the substrate 11 was irradiated with UV light, from the sealing member side made of the glass substrate, and thus the adhesive was cured to thereby seal the organic EL element 30.

Note that, in the formation of the organic EL element 30, a light emitting region of 4.5 cm×4.5 cm in the center of the substrate 11 of 5 cm×5 cm was set by the use of a deposition mask for forming each layer, and a non-light emitting region was provided around the whole peripheral of the light emitting region with a width of 0.25 cm. Furthermore, the counter electrode 5 used as the anode and the transparent electrode 2 used as the cathode were formed so as to be insulated by the positive hole transport/injection layer 31 to the electron transport/injection layer 34, and so that the terminal parts were pulled out to the peripheral of the substrate 11.

In the way described above, there was obtained the organic EL element 101 in which the organic EL element 30 was sealed by the sealing member and the adhesive. In the organic EL element, the emitted light h of each color generated in the light-emitting layer 32 is extracted from the side opposite to the substrate 11.

### <Production Procedures of Organic EL Element 102>

An organic EL element 102 was produced in the similar procedures to those in the above organic EL element 101 except that a lithium fluoride layer (salt) composed of lithium fluoride (LiF) was formed before formation of the transparent electrode made of silver (Ag) as described below.

First, the substrate 11 where the light-emitting unit 3 was formed was fixed onto a substrate holder of a commercial vacuum vapor-deposition apparatus, lithium fluoride (LiF) was placed in a tantalum resistive heating boat, and then the substrate holder and the resistive heating boat were attached to a first vacuum tank of the vacuum vapor-deposition apparatus. Furthermore, silver (Ag) was placed in a tungsten resistive heating boat, and the tungsten resistive heating boat containing silver was attached to a second vacuum tank of the vacuum vapor-deposition apparatus.

Next, after reduction of a pressure of the first vacuum tank to 4×10⁻⁴ Pa, the resistive heating boat containing lithium fluoride (LiF) was heated by application of an electric current, and the lithium fluoride layer (salt) having a thickness of 1 nm was deposited on the substrate 11 at a vapor-deposition rate of 0.1 nm/sec to 0.2 nm/sec.

Next, the substrate 11 obtained by forming layers up to the lithium fluoride layer (salt) was transferred to the second vacuum tank under vacuum, the transparent electrode 2 composed of silver was formed in the procedures similar to the production procedures explained in the organic EL element 101.

### <Production Procedures of Organic EL Element 103>

An organic EL element 103 was produced in the similar procedures to those in the above organic EL element 102 except that the transparent electrode 2 was formed by replacing the lithium fluoride layer (salt) with a potassium fluoride layer (salt) composed of potassium fluoride (KF). Note that the potassium fluoride layer was produced in the similar procedures to those in the production procedures in the lithium fluoride layer of the organic EL element 102.

### <Production Procedures of Organic EL Element 104>

An organic EL element 104 was produced in the similar procedures to those in the above organic EL element 102 except that the transparent electrode 2 was formed of aluminum (Al) in the following way.

First, the substrate 11 where the light-emitting unit 3 was formed was fixed onto a substrate holder of a commercial vacuum vapor-deposition apparatus, lithium fluoride (LiF) was placed in a tantalum resistive heating boat, and then the substrate holder and the resistive heating boat were attached to a first vacuum tank of the vacuum vapor-deposition apparatus. Furthermore, aluminum (Al) was placed in a tungsten resistive heating boat, and the tungsten resistive heating boat containing aluminum was attached to a second vacuum tank of the vacuum vapor-deposition apparatus.

Next, in the first vacuum tank of the vacuum vapor-deposition apparatus, a lithium fluoride layer (salt) composed of lithium fluoride (LiF) was formed in the similar procedures to the production procedures explained in the organic EL element 102.

Next, the substrate 11 obtained by forming layers up to the lithium fluoride layer (salt) was transferred to the second vacuum tank under vacuum, after reduction of a pressure of the second vacuum tank to 4×10⁻⁴ Pa, the resistive heating boat containing aluminum and attached to the second vacuum tank was heated by application of an electric current. Thereby, a transparent electrode 2 composed of aluminum (Al) having a thickness of 10 nm was formed at a vapor-deposition rate of 0.3 nm/sec.

### <Production Procedures of Organic EL Element 105>

An organic EL element 105 was produced in the similar procedures to those in the above organic EL element 102 except that the transparent electrode 2 was formed by replacing the lithium fluoride layer (salt) with a calcium-containing layer (salt) composed of calcium (Ca). Note that the calcium-containing layer was produced in the similar procedures to those in the production procedures in the lithium fluoride layer of the organic EL element 102.

### <Production Procedures of Organic EL Element 106>

An organic EL element 106 was produced in the similar procedures to those in the above organic EL element 105 except that the transparent electrode 2 was formed of silver palladium (AgPd) in the following way.

First, the substrate 11 where the light-emitting unit 3 was formed was fixed onto a substrate holder of a commercial vacuum vapor-deposition apparatus, calcium (Ca) was placed in a tantalum resistive heating boat, and then the substrate holder and the resistive heating boat were attached to a first vacuum tank of the vacuum vapor-deposition apparatus. Furthermore, each of silver (Ag) and palladium (Pd) was placed in each of the tungsten resistive heating boats, and the tungsten resistive heating boat containing silver (Ag) or palladium (Pd) was attached to a second vacuum tank of the vacuum vapor-deposition apparatus.

Next, in the first vacuum tank of the vacuum vapor-deposition apparatus, a calcium-containing layer composed of calcium (Ca) was formed in the similar procedures to the production procedures explained in the organic EL element 105.

Next, after reduction of a pressure of the second vacuum tank of the vacuum vapor-deposition apparatus to 4×10⁻⁴ Pa, the heating boats containing silver (Ag) and palladium (Pd) were heated by application of an electric current. At this time, the vapor-deposition rates were adjusted by regulation of currents to be applied to the resistive heating boats, and there was formed a transparent electrode 2 in which 5 atm % palladium (Pd) was added to silver (Ag) by co-deposition.

### <Production Procedures of Organic EL Elements 107 and 108>

Organic EL elements 107 and 108 were produced in the similar procedures to those in the above organic EL element 106 except that the transparent electrodes 2 were formed by the use of the respective compounds mentioned in the following Table 1. Note that the transparent electrodes 2 made of the respective compounds were produced in the similar production procedures to the production method of the transparent electrode 2 composed of silver palladium (AgPd) of the organic EL element 106.

### <Production Procedures of Organic EL Elements 109 to 113>

Organic EL elements 109 to 113 were produced in the similar procedures to those in the above organic EL element 105 except that the calcium-containing layers (salts) each having the thickness mentioned in the following Table 1 were formed.

### <Production Procedures of Organic EL Elements 114 to 118>

Organic EL elements 114 to 118 were produced in the similar procedures to those in the above organic EL element 105 except that the transparent electrodes 2 each having the thickness mentioned in the following Table 1 were formed.

### <Evaluation 1 of Each Organic EL Element of Example>

As to the organic EL elements 101 to 118 produced above, the (1) driving voltage (V), (2) light emission efficiency, and (3) high-temperature storage property (ΔV) were measured by driving the organic EL elements through the use of the transparent electrode 2 as a cathode and the counter electrode 5 as an anode. The results are shown together in the following Table 1.

(1) In the measurement of the driving voltage, a voltage when a front luminance at the transparent electrode 2 side (namely, the sealing member side) of the organic EL elements 101 to 118 is 1000 cd/m² is set as the driving voltage. Note that the spectral emission luminance meter CS-2000 (manufactured by KONICA MINOLTA SENSING) was used for measurement of the luminance. The smaller the obtained voltage is, the better the result is.

(2) In the light emission efficiency, the front luminance of the organic EL elements 101 to 118 was measured by the use of the spectral emission luminance meter CS-2000 (manufactured by KONICA MINOLTA SENSING), the electric power efficiency at a front luminance of 1000 cd/m² was evaluated. Note that the evaluation of the light emission efficiency was carried out on the basis of a relative value when the light emission efficiency of the organic EL element 104 is assumed to be 100.

(3) In the measurement of the high temperature storage property, there were measured sheet resistances of the organic EL elements 101 to 118 after storage for 300 hours under a high-temperature environment (temperature 85° C., dry condition). Then, the increased ratio of the sheet resistance after storage with respect to the sheet resistance before storage is calculated as the high-temperature storage property (ΔV). The smaller the obtained voltage is, the better the result is. These results are shown together in the following Table 1.

The configurations of the organic EL elements 101 to 118, the measurement results of the driving voltage (V), the light emission efficiency, and the high-temperature storage property (ΔV) are shown in the following Table 1.

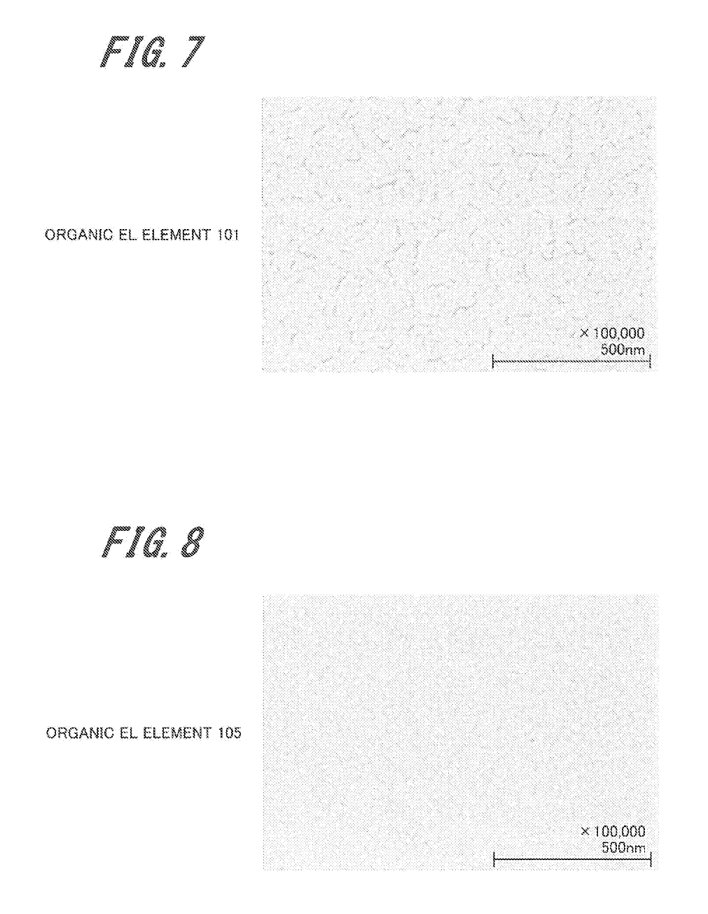

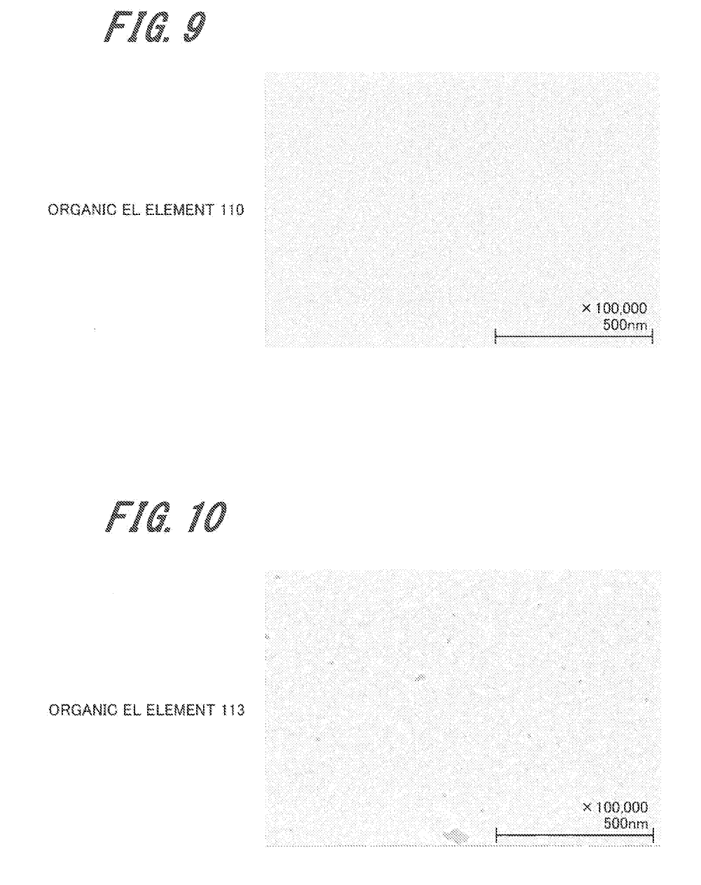

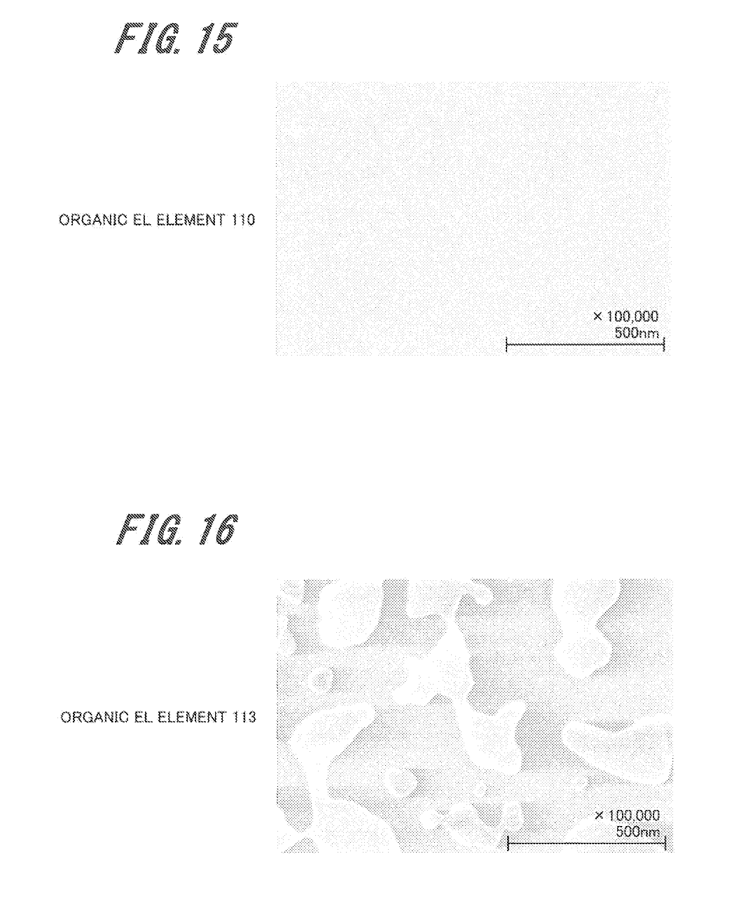

TABLE 1

| | | | | | Evaluation results | | | | |
|---|---|---|---|---|---|---|---|---|---|
| | | | | | | | High- | | |
| | | | Transparent | | | | temperature | | |
| | Salt | | electrode | | Driving | Light | storage | | |
| | | Thickness | | Thickness | voltage | emission | property | Corresponding | |
| Sample | Salts | [nm] | Compound | [nm] | [V] | efficiency | [ΔV] | FIG. | Note |
| 101 | — | — | Ag | 10 | Not emitted | Not emitted | — | FIG. 7 | Comparative |
| 102 | LiF | 1 | Ag | 10 | Not emitted | Not emitted | — | — | Comparative |
| 103 | KF | | | | | | | | |
| 104 | LiF | 1 | Al | 10 | 5.5 | 100 | 0.56 | — | Comparative |
| 105 | Ca | 1 | Ag | 10 | 5.3 | 235 | <0.1 | FIGS. 8, 13, 14 | Present invention |
| 106 | Ca | 1 | AgPd | 10 | 5.1 | 233 | <0.1 | — | Present |
| 107 | | | AgAu | | 5.2 | 240 | <0.1 | | invention |
| 108 | | | AgCu | | 5.0 | 234 | <0.1 | | |
| 109 | Ca | 0.05 | Ag | 10 | 5.9 | 233 | 0.10 | — | Present |
| 110 | | 0.1 | | | 5.7 | 235 | <0.1 | FIGS. 9, 15 | invention |
| 111 | | 0.5 | | | 5.3 | 229 | <0.1 | — | |
| 112 | | 2 | | | 5.3 | 238 | <0.1 | — | |
| 113 | | 3 | | | 6.1 | 237 | 2.53 | FIGS. 10, 16 | |
| 114 | Ca | 1 | Ag | 5 | 5.6 | 233 | 1.88 | — | Present |
| 115 | | 1 | | 7.5 | 5.2 | 242 | <0.1 | | invention |
| 116 | | 1 | | 15 | 5.3 | 216 | <0.1 | | |
| 117 | | 1 | | 20 | 5.2 | 178 | <0.1 | | |
| 118 | | 1 | | 30 | 5.4 | 137 | <0.1 | | |

### <Evaluation Results 1 of Example>

As is clear from Table 1, the organic EL elements 201 to 203 in which a calcium-containing layer is not provided between a transparent electrode composed of silver (Ag) and a light-emitting unit did not emit light. From the results, it has been found that, in the organic EL element in which the calcium-containing layer is not provided between the light-emitting unit and the transparent electrode composed of silver (Ag), the silver electrode (transparent electrode) having a small thickness cannot be used as a cathode.

Furthermore, light emission was confirmed as to the organic EL element 104 having the transparent electrode composed of aluminum (Al) which has a smaller work function than silver (Ag).

Here, in making a comparison between the organic EL element 104 in which light emission has been confirmed and the organic EL element 105 in which the calcium-containing layer is provided between the transparent electrode composed of silver (Ag) and the light-emitting unit, the organic EL element 105 having the transparent electrode composed of silver (Ag) can give better results in the driving voltage and the light emission efficiency. From the result, it is considered that there can be formed the transparent electrode more excellent in conductivity and light-transmitting property than those of the transparent electrode composed of aluminum to be generally used as a cathode material, by provision of the calcium-containing layer between the light-emitting unit and the transparent electrode composed of silver (Ag).

Moreover, in making a comparison among the organic EL elements 105, 106 to 108, namely, the respective organic EL elements in which only the compound constituting the transparent electrode is different, the organic EL elements 106 to 108 each having the transparent electrode composed of the alloy containing silver (Ag) as a main component give good results in the driving voltage, the light-emission efficiency and the high temperature storage property in the similar way to those of the organic EL element 105.

In addition, in making a comparison among the organic EL elements 105, 109 to 113, namely, the respective organic EL elements in which only the thickness of the calcium-containing layer is different, the organic EL elements 105, 109 to 112 having the calcium-containing layer constituted within a thickness range of 2 nm or less give better results in the driving voltage and the high temperature storage property than those of the organic EL element 113 constituted outside the numerical thickness range.

Furthermore, the organic EL elements 105, 108 to 112 having the calcium-containing layer within a thickness range of 0.1 to 2 nm give further better results in the driving voltage and the high temperature storage property than the organic EL element constituted outside the numerical thickness range.

Moreover, particularly, it has been confirmed that the organic EL elements 105, 111, and 112 having the calcium-containing layer within a thickness range of 0.5 to 2 nm is further suppressed in the driving voltage in comparison with the organic EL element constituted outside the numerical thickness range.

Furthermore, in making a comparison among the organic EL elements 105, 114 to 118, namely, the respective organic EL elements in which only the thickness of the transparent electrode composed of silver (Ag) is different, the organic EL elements 105, 115 to 117 having the transparent electrode constituted within a thickness range of 6 to 20 nm give better results in the driving voltage and the high temperature storage property than those of the organic EL elements 114 and 118 constituted outside the numerical thickness range.

From the results, it has been confirmed that the silver electrode (transparent electrode) having a small thickness can be used as a cathode by the formation of the calcium-containing layer between the transparent electrode composed of silver (Ag) and the light-emitting unit. Moreover, it is considered that the calcium (Ca) atom of the calcium-containing layer and the silver (Ag) atom of the transparent electrode easily interact with each other by making the thickness of the calcium-containing layer or/and the transparent electrode composed of silver (Ag) optimum and thus the transparent electrode excellent in the conductivity and the light-transmitting property is formed.

### <Evaluation 2 of Each Sample of Example>

There are shown, in FIGS. 7 to 10, the secondary electronic images (SEM image magnification: 100 thousand) of the above respective organic EL elements observed by a scanning electron microscope.

Here, there are shown the SEM images of the surfaces to be analyzed of the respective transparent electrodes in the organic EL element 101 in FIG. 7, in the organic EL element 105 in FIG. 8, in the organic EL element 110 in FIG. 9, and in the organic EL element 113 in FIG. 10. Namely, these are SEM images when each configuration shown in above Table 1 is provided on the organic material B, shown by the above-described structural formula, constituting the electron transport/injection layer of the light-emitting unit.

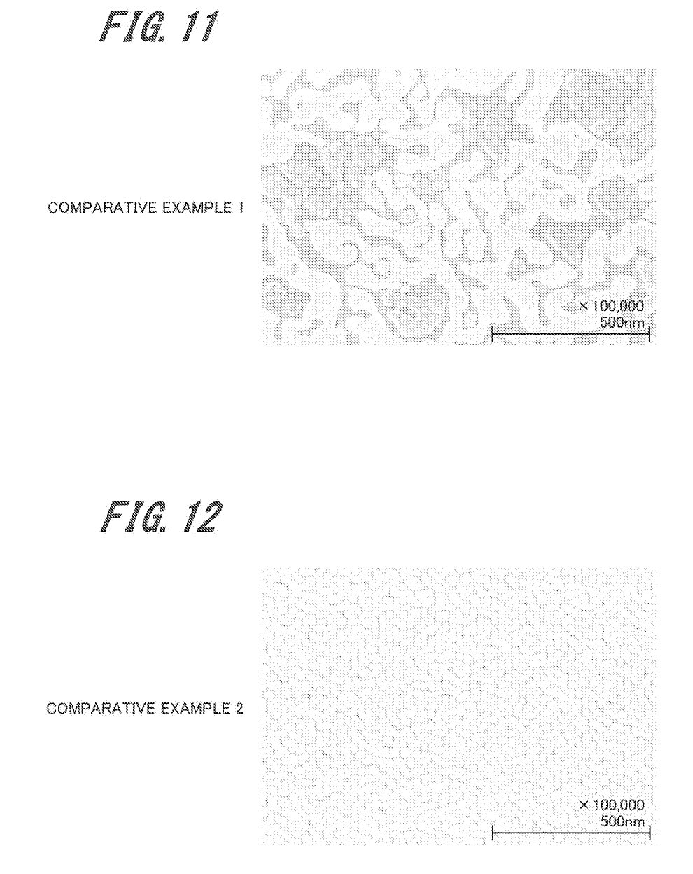

Furthermore, FIG. 11 shows, as Comparative Example 1, the SEM image when the transparent electrode produced in the organic EL element 101 is provided on a glass substrate. Moreover, FIG. 12 shows, as Comparative Example 2, the SEM image when the transparent electrode produced in the organic EL element 101 is provided on the organic material A shown by the above-described structural formula.

### <Evaluation Results 2 of Example>

As shown in FIGS. 7 to 12, in making a comparison among the transparent electrodes of the respective organic EL elements, as explained below, it is clear that a deposition state of the silver electride having a small thickness which constitutes the transparent electrode is different depending on the configuration of a layer formed adjacent to the transparent electrode.

Namely, as shown in FIG. 7, the organic EL element 101 not having the calcium-containing layer between the light-emitting unit 3 (organic material B) and the transparent electrode has low continuity of silver (white portion in the figure) constituting the transparent electrode, and portions without covering of the transparent electrode (black portion in the figure) are conspicuous. Furthermore, as shown in FIGS. 11 and 12, the transparent electrode provided on the glass substrate and the transparent electrode provided on the organic material A have further lower continuity of silver than the transparent electrode of the above organic EL element 101, and thus portions without covering of the transparent electrode (black portion in the figure) are conspicuous.

On the other hand, as shown in FIGS. 8 to 10, the silver constituting the transparent electrode is continuous in the organic EL elements 105, 110, and 113 having the calcium-containing layer 1 between the light-emitting unit 3 and the transparent electrode. Therefore, it has been confirmed that there is formed the transparent electrode having a stable film quality and a uniform thickness although the electrode has a small thickness.

Furthermore, in making a comparison among the organic EL elements 105, 110, and 113 which have the similar layer configuration but are different only in the thickness of the calcium-containing layer 1, in the organic EL elements 105 and 110 in which the thickness of the calcium-containing layer 1 is 2.0 nm or less, there is almost no portion without covering of the silver, and it has been confirmed that the continuity of the silver constituting the transparent electrode is high.

### <Evaluation 3 of Each Sample of Example>

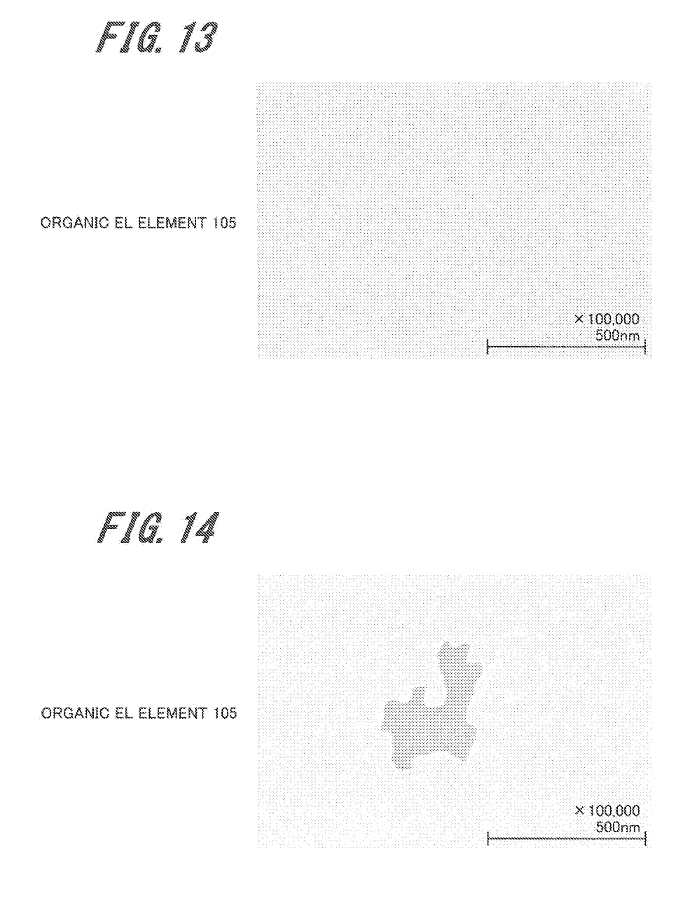

FIGS. 13 to 16 show the SEM images of the surfaces to be analyzed after storage of the organic EL elements 105, 110, and 113 in which a stable film quality has been confirmed, for 300 hours under the high temperature environment (temperature 85° C., dry condition).

### <Evaluation Results 3 of Example>

As shown in FIGS. 13 to 16, in making a comparison among the transparent electrodes of the organic EL elements 105, 110, and 113 after storage at a high temperature, as explained below, it is clear that a deposition state of the silver electride having a small thickness constituting the transparent electrode is different depending on the thickness of the calcium-containing layer. Note that FIG. 14 shows a part (another image) of the organic EL element 105 having a thickness of the calcium-containing layer of 1.0 nm.

Namely, as shown in FIGS. 13 to 16, in the organic EL elements 105 and 110 each having a thickness of the calcium-containing layer of 2.0 nm or less, the fine defective portions at the time of film deposition of the transparent electrode are not spread after the high temperature storage, and it has been confirmed that the continuity of the silver constituting the transparent electrode is high. However, as shown in G. 14, in the organic EL element 105, it has been confirmed that the fine defective portions at the time of film deposition of the transparent electrode are partially spread.

On the other hand, as shown in FIG. 16, in the organic EL element 113 having a thickness of the calcium-containing layer of 3.0 nm, the fine defective portions at the time of film deposition are spread after the high temperature storage, and continuity of the transparent electrode is low, and thus portions without covering of the transparent electrode (black portion in the figure) are conspicuous.

From the evaluation results 2 and 3, it is considered that the calcium (Ca) atom of the calcium-containing layer and the silver (Ag) atom of the transparent electrode interact with each other to thereby form the transparent electrode having a stable film quality and a uniform thickness although the electrode has a small thickness, by the formation of the calcium-containing layer between the light-emitting unit and the transparent electrode. Furthermore, particularly, it is considered that the calcium (Ca) atom and the silver (Ag) atom easily interact with each other by making the thickness of the calcium-containing layer optimum and thus the transparent electrode having a further stable film quality is formed.

Note that the present invention is not limited to the configurations described in the above exemplary embodiments, and additional various modifications and changes can be made within the scope not departing from the configuration of the present invention.

### REFERENCE SIGNS LIST

10, 10′, 20, 20′, 20″, 30: Organic EL element
11: Substrate
1, 1″: Calcium-containing layer
2: Transparent electrode
3: Light-emitting unit
5: Counter electrode
25-1: First counter electrode
25-2, 25-2″: Second counter electrode
23-1: First light-emitting unit
23-2: Second light-emitting unit
31: Positive hole transport/injection layer
33: Positive hole-blocking layer
34: Electron transport/injection layer
h: Emitted light

1. An organic electroluminescent element comprising:
a transparent electrode composed of silver as a main component;
a counter electrode arranged so as to face the transparent electrode; and
a light-emitting unit sandwiched between the transparent electrode and the counter electrode,
wherein a calcium-containing layer is provided adjacent to the transparent electrode between the transparent electrode and the light-emitting unit, and
the transparent electrode is used as a cathode and the counter electrode is used as an anode.

2. The organic electroluminescent element according to claim 1, wherein the counter electrode is defined as a first counter electrode, and a second counter electrode is arranged so as to face the transparent electrode on an opposite side of the first counter electrode,
the light-emitting unit is a first light-emitting unit, and a second light-emitting unit is sandwiched between the transparent electrode and the second counter electrode.

3. The organic electroluminescent element according to claim 2, wherein the transparent electrode is used as an anode with respect to the second counter electrode, and
the second counter electrode is used as a cathode with respect to the transparent electrode.

4. The organic electroluminescent element according to claim 2, wherein the calcium-containing layer is provided adjacent to the second light-emitting unit between the transparent electrode and the second light-emitting unit,
the transparent electrode is used as a cathode with respect to the second counter electrode, and
the second counter electrode is used as an anode with respect to the transparent electrode.

5. The organic electroluminescent element according to claim 2, wherein the organic electroluminescent element is driven by application of a voltage only to the first counter electrode and the second counter electrode.

6. The organic electroluminescent element according to claim 2, wherein the organic electroluminescent element is driven by application of a voltage to the first counter electrode, the second counter electrode, and the transparent electrode.

7. The organic electroluminescent element according to claim 1, wherein a thickness of the calcium-containing layer is within the range of 2 nm or less.

8. The organic electroluminescent element according to claim 1, wherein a thickness of the transparent electrode is within the range of 6 to 20 nm.
